(19) United States
(12) Patent Application Publication
(10) Pub. No.: US 2026/0026058 A1
(43) Pub. Date: Jan. 22, 2026

(54) SIGE:B TO RETARD VIA BACKSIDE ETCH

(71) Applicant: Taiwan Semiconductor Manufacturing Co., Ltd., Hsinchu (TW)

(72) Inventors: Dah-Jin Tai, Hsinchu (TW); Chien-Chia Cheng, Hsinchu (TW); Chien-I Kuo, Zhubei City (TW); Ming-Hua Yu, Hsinchu (TW); Chii-Horng Li, Zhubei City (TW)

(21) Appl. No.: 18/777,337

(22) Filed: Jul. 18, 2024

(51) Int. Cl. H01L 29/08; H01L 29/06; H01L 29/36; H01L 29/423; H01L 29/66; H01L 29/775; H01L 29/786

(52) U.S. Cl. CPC H10D 62/151; H10D 30/014; H10D 30/43; H10D 30/6735; H10D 30/6757; H10D 62/121; H10D 62/60

(57) ABSTRACT

A semiconductor device, a nano-FET, and a method of manufacturing a semiconductor device is provided. The semiconductor device a substrate, a source/drain region, a retarding layer between the substrate and the source/drain region that has a slower etch rate when exposed to an etch than does the substrate and the source/drain region, and the through silicon via (TSV) electrically connecting the source/drain region to a backside of the semiconductor device, wherein the TSV penetrates through the substrate, the retarding layer, and a portion of the source/drain region.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6A, 6B, 7A, 7B 8A, 8B, 9A, 9B, 9C, 9D, 9E, 9F, 10A, 10B, 11A, 11B, 11C, 12A, 12C, 12D, 12E, 12F, 12G, 13A, 13B, 13C, 13D, 14A, 14B, 14C, 15A, 15B, 16A, 16B, 17A, 17B, 18A, 18B, 19A, 19B, 19C, 20A, 20B, 20C, 21A, 21B, 21C, 23A, and 23B are cross-sectional views of intermediate stages in the manufacturing of nano-FETs, in accordance with some embodiments.

FIG. 12B is a profile of an impurity concentration gradient, in accordance with some embodiments.

FIGS. 22A, 22B, 22C, and 24 are cross-sectional views of a nano-FET, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments are described below in a particular context, a die comprising nano-FETs that utilizes a retarding layer to limit penetration of a backside through silicon via into the source/drain region of a nano-FET and maintains greater source/drain efficiency and operational characteristics. Various embodiments may be applied, however, to dies comprising other types of transistors (e.g., fin field effect transistors (FinFETs), planar transistors, or the like) in lieu of or in combination with the nano-FETs.

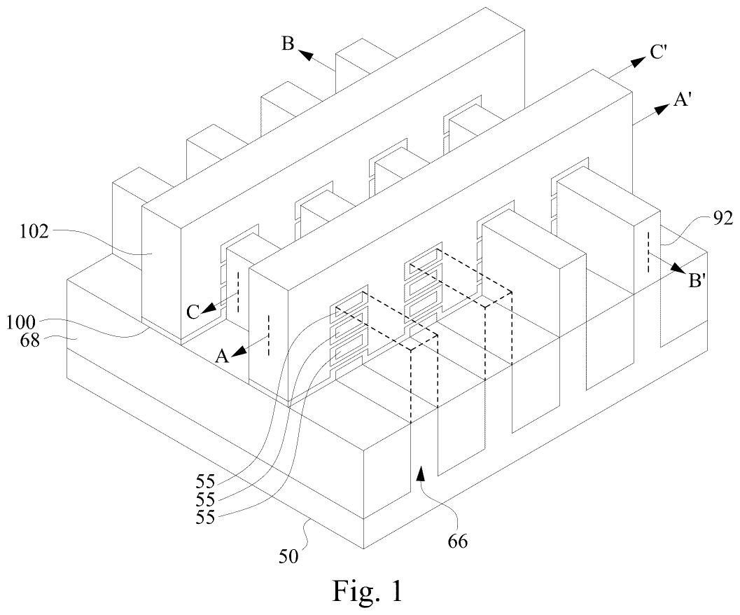

FIG. 1 illustrates an example of nano-FETs (e.g., nanowire FETs, nanosheet FETs (Nano-FETs), or the like) in a three-dimensional view, in accordance with some embodiments. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Isolation regions 68 are disposed between adjacent fins 66, which may protrude above and from between neighboring isolation regions 68. Although the isolation regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring isolation regions 68.

Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

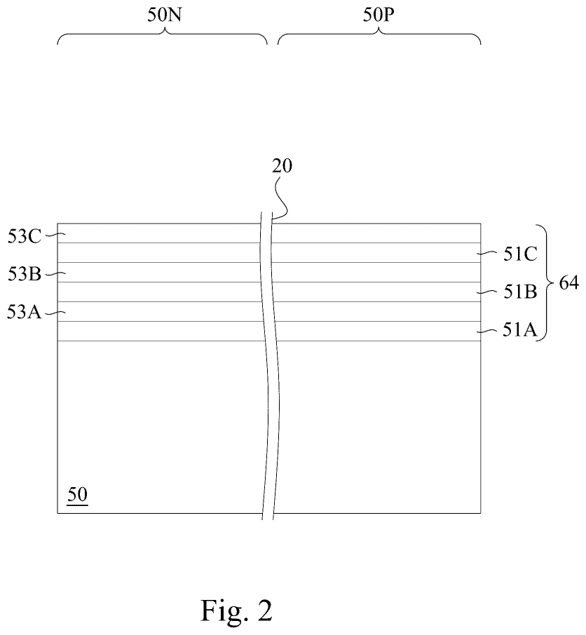

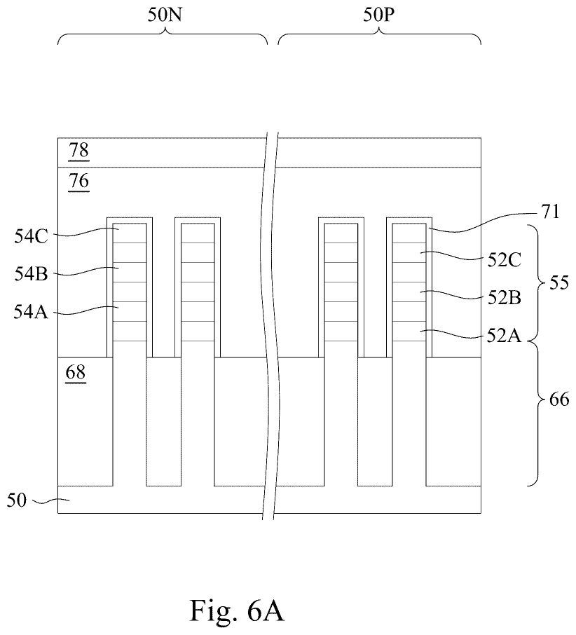

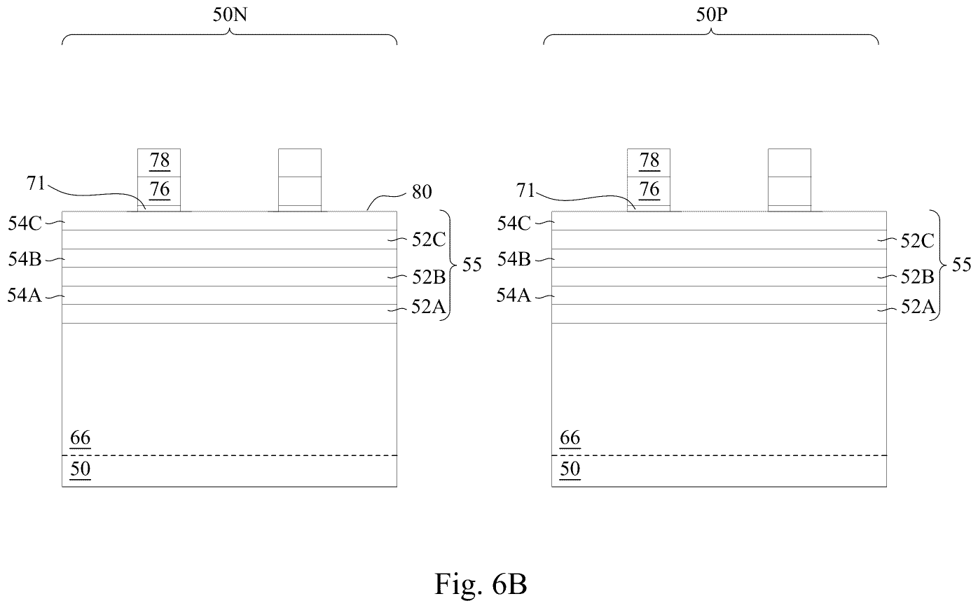

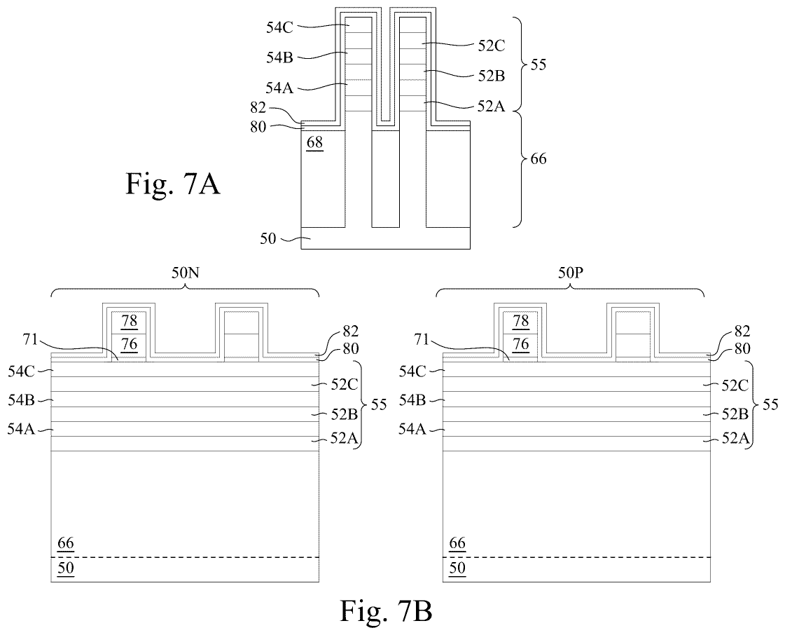

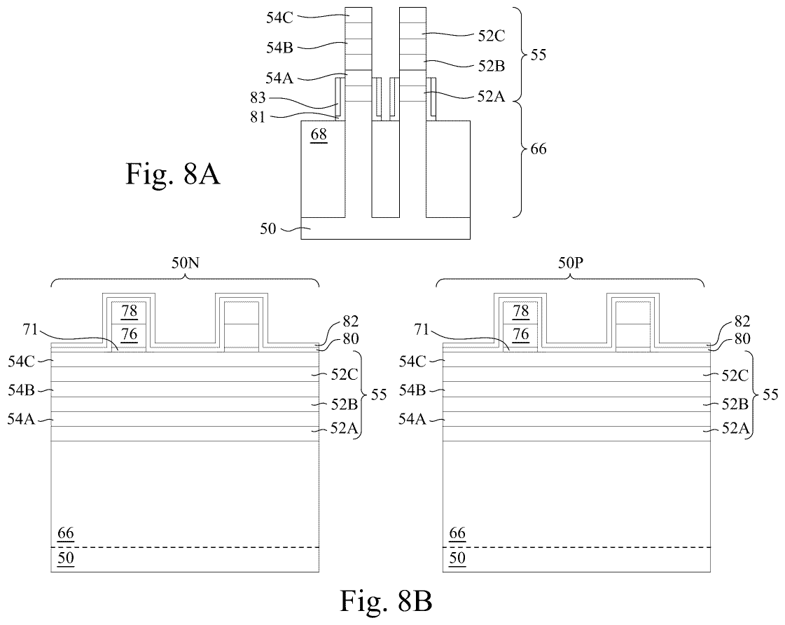

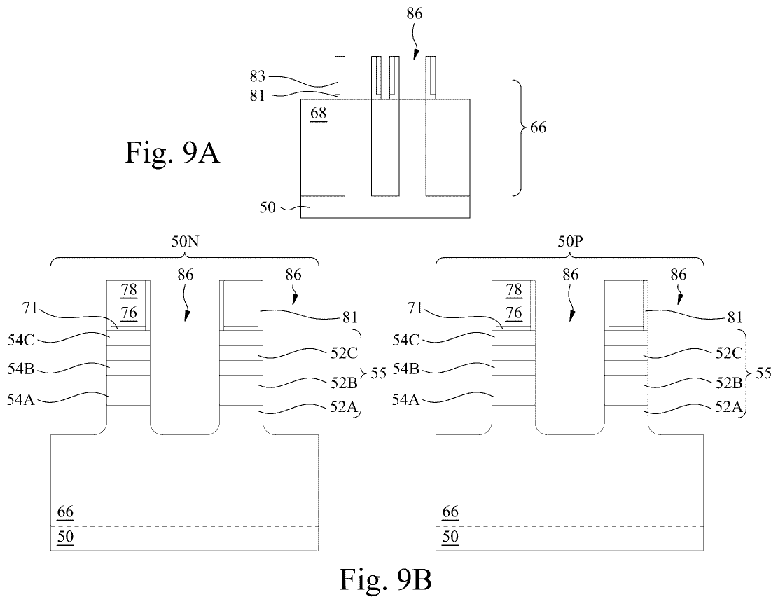

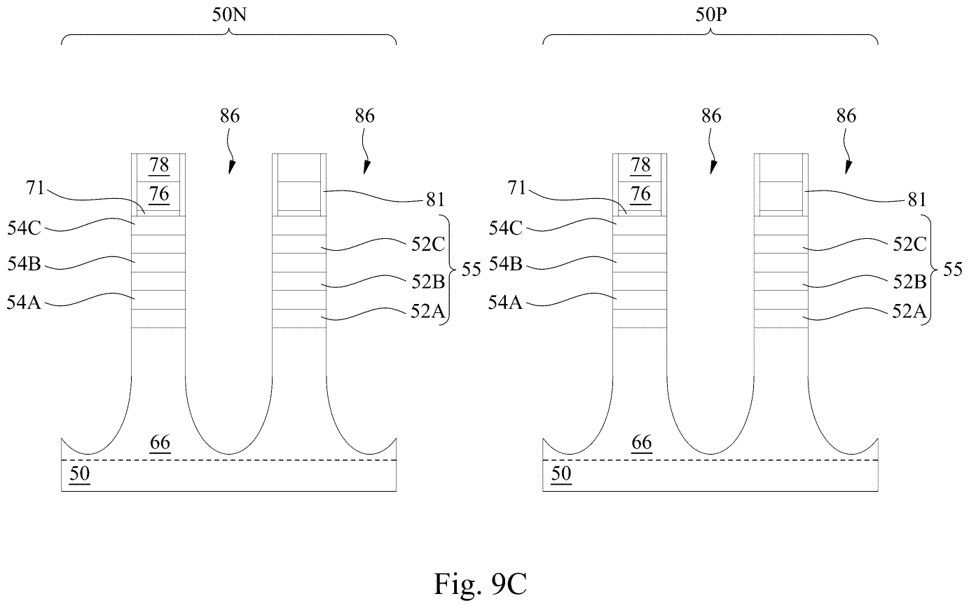

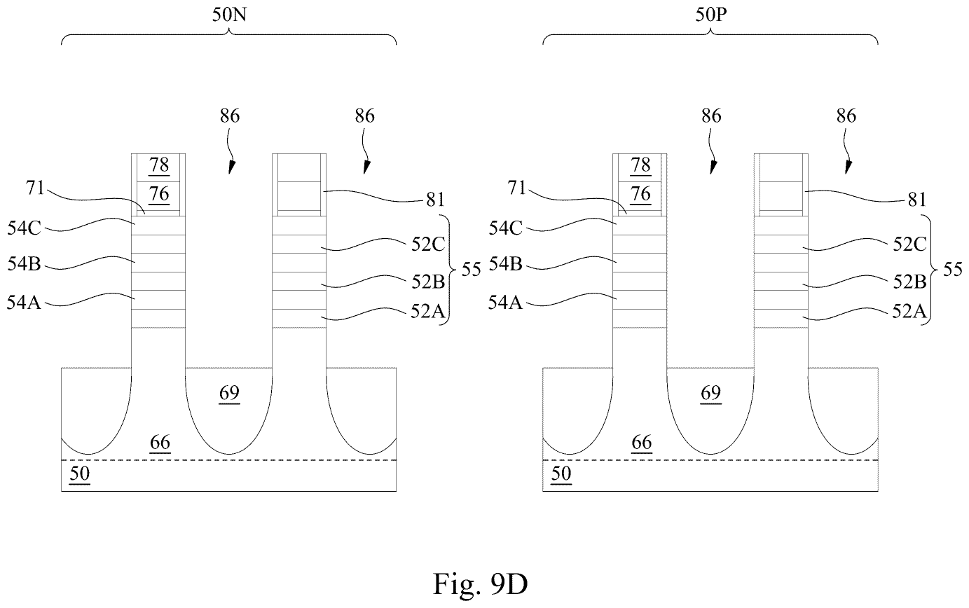

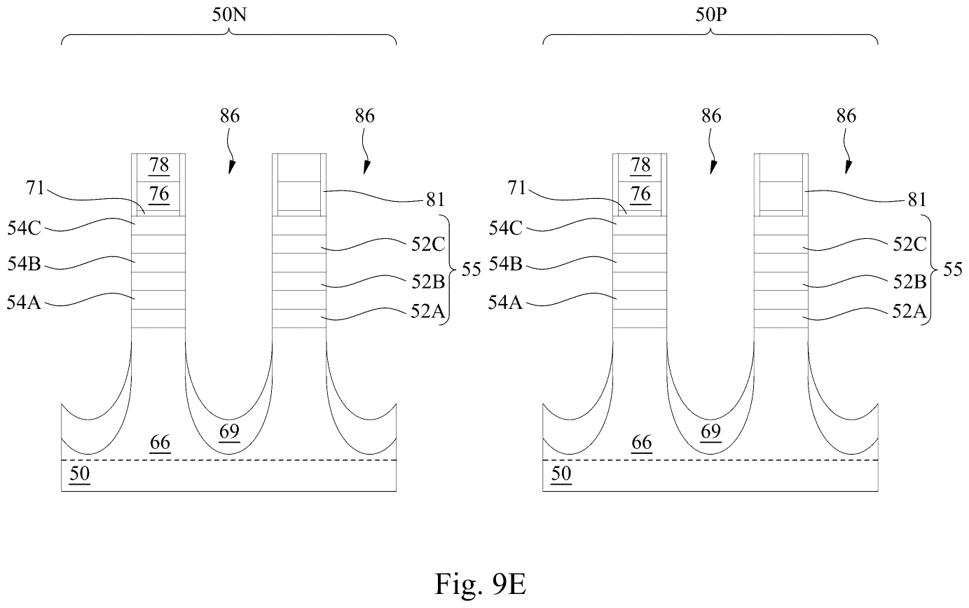

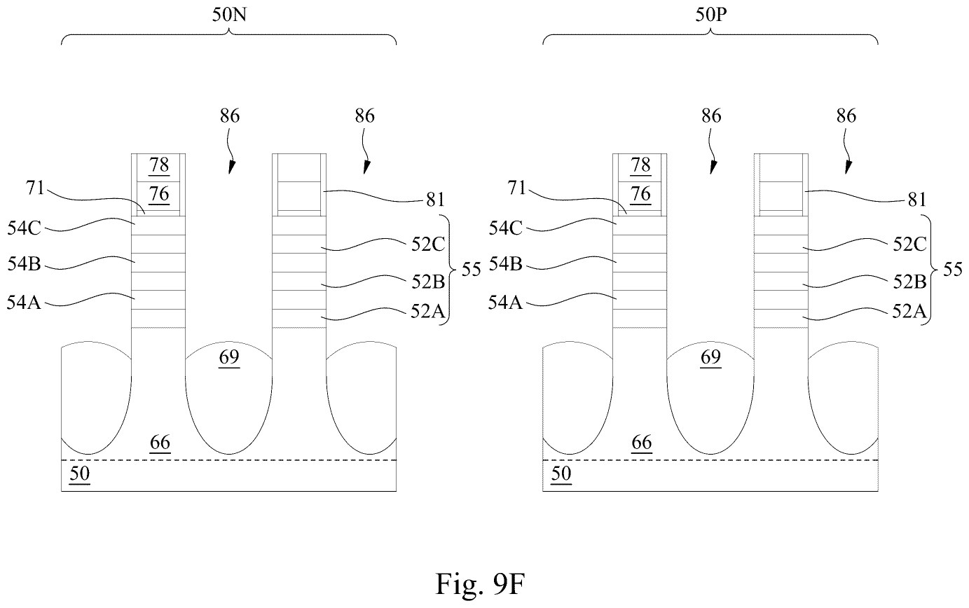

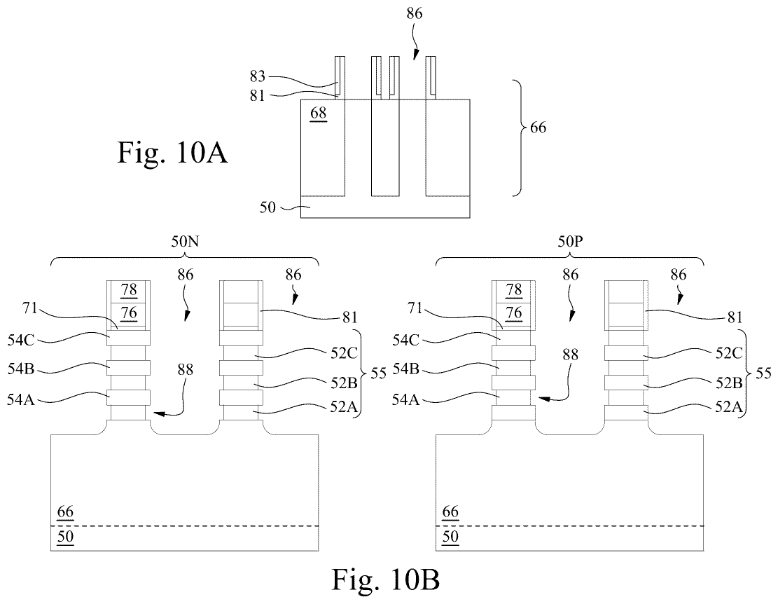

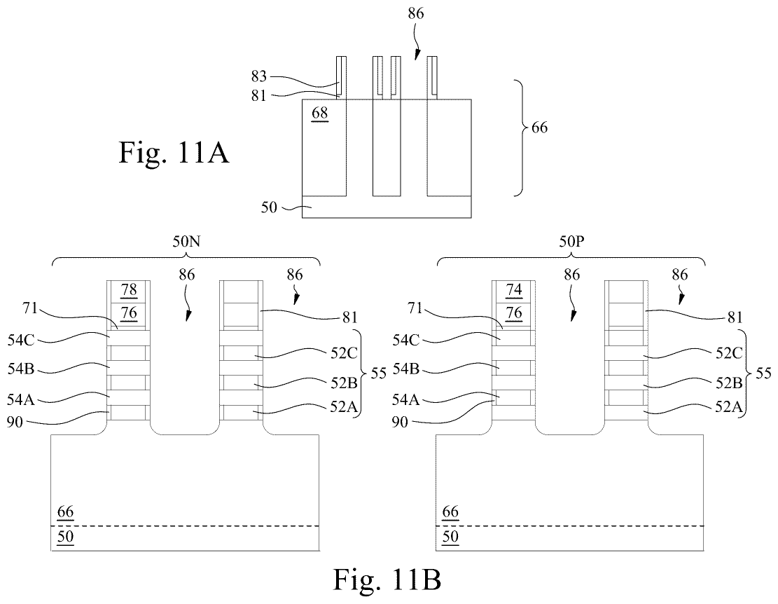

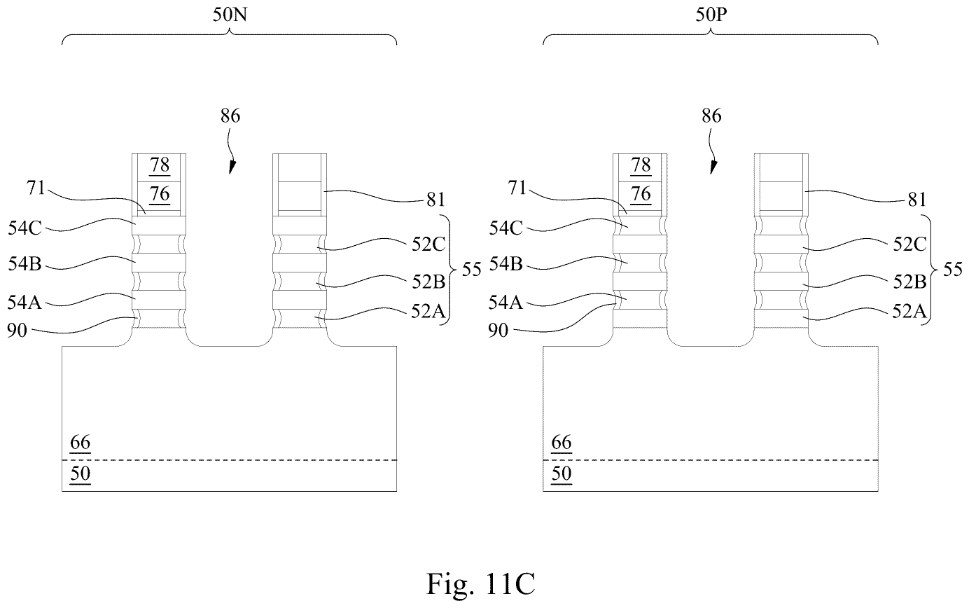

FIGS. 2 through 24 are cross-sectional views of intermediate stages in the manufacturing of nano-FETs, in accordance with some embodiments. FIGS. 2 through 5, 6A, 14A, 15A, 16A, 17A, 18A, 19A, 20A, 21A, and 22A illustrate reference cross-section A-A′ illustrated in FIG. 1. FIGS. 6B, 7B, 8B, 9B-9F, 10B, 11B, 11C, 12A, 12C-12G, 13B, 13D, 13B, 14B, 15B, 16B, 17B, 18B, 19B, 20B, 21B, and 22B illustrate reference cross-section B-B′ illustrated in FIG. 1. FIGS. 7A, 8A, 9A, 10A, 11A, 13A, 13C, 14C, 19C, 20C, 21C, and 22C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the second semiconductor layers 53 will be removed and the first semiconductor layers 51 will be patterned to form channel regions of nano-FETs in the p-type region 50P. Also, the first semiconductor layers 51 will be removed and the second semiconductor layers 53 will be patterned to form channel regions of nano-FETs in the n-type region 50N. Nevertheless, in some embodiments the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P.

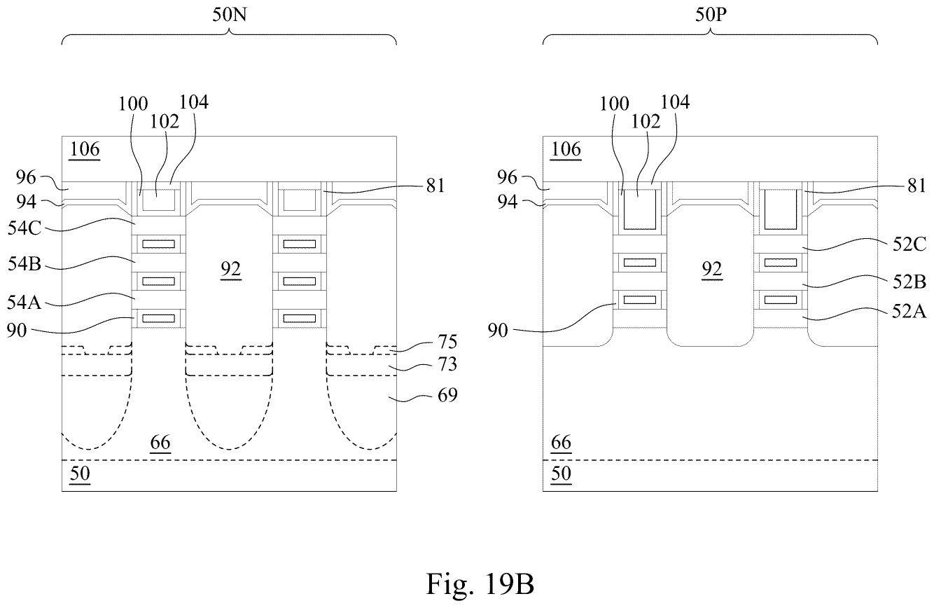

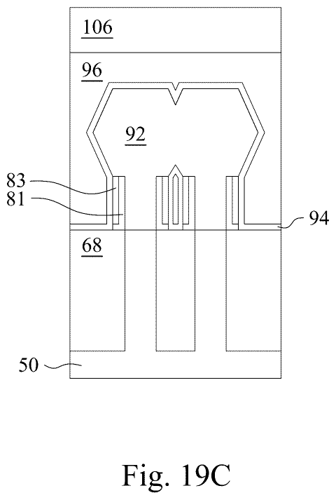

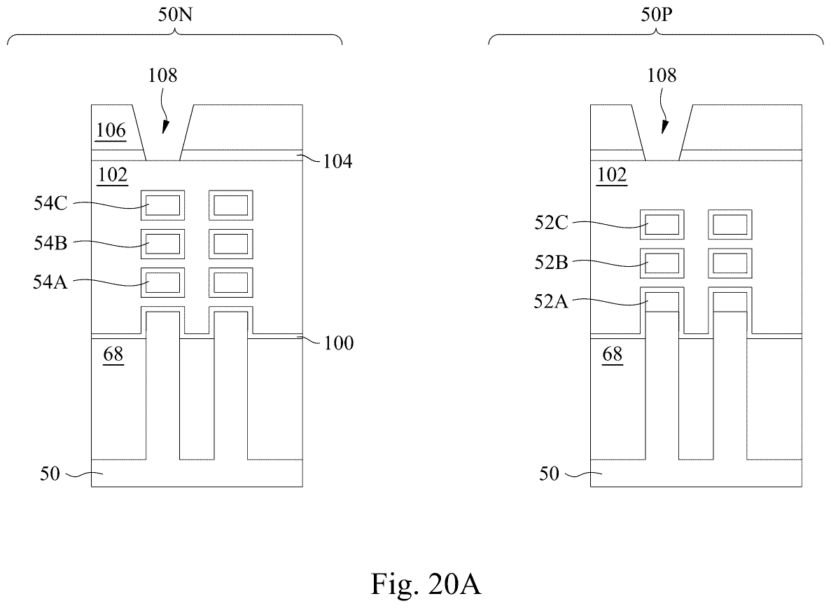

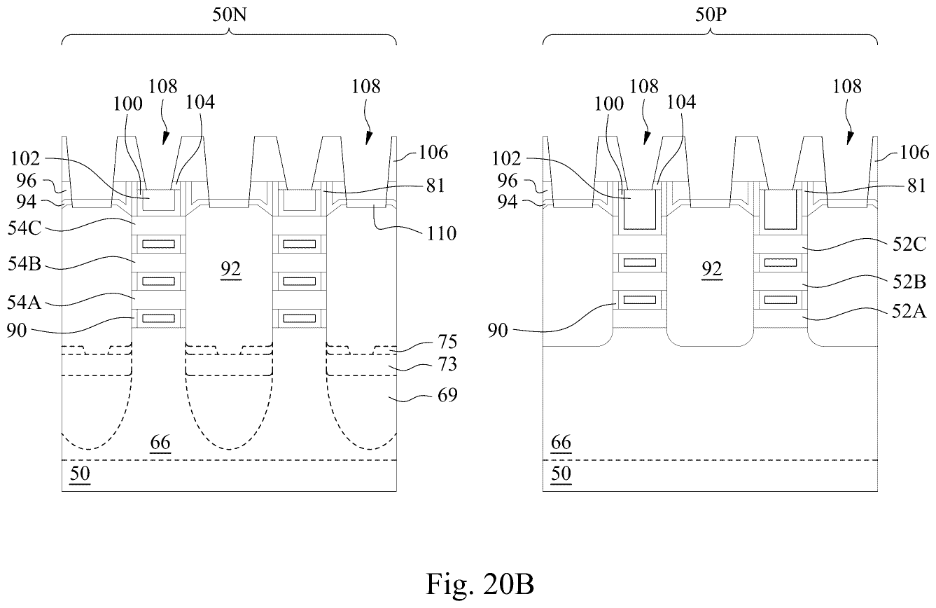

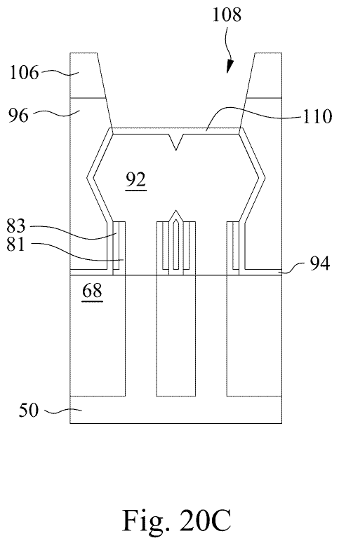

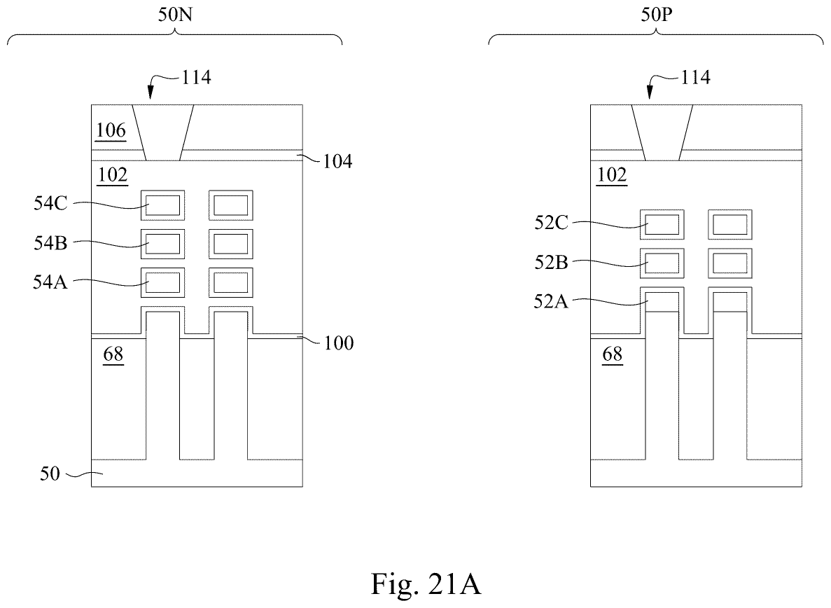

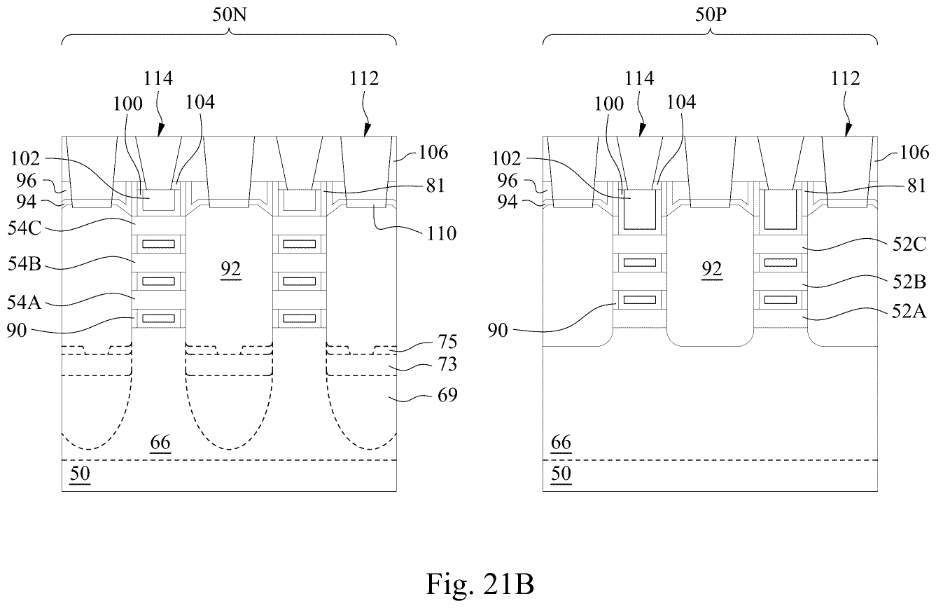

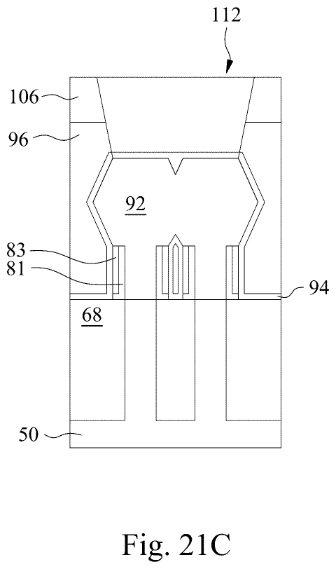

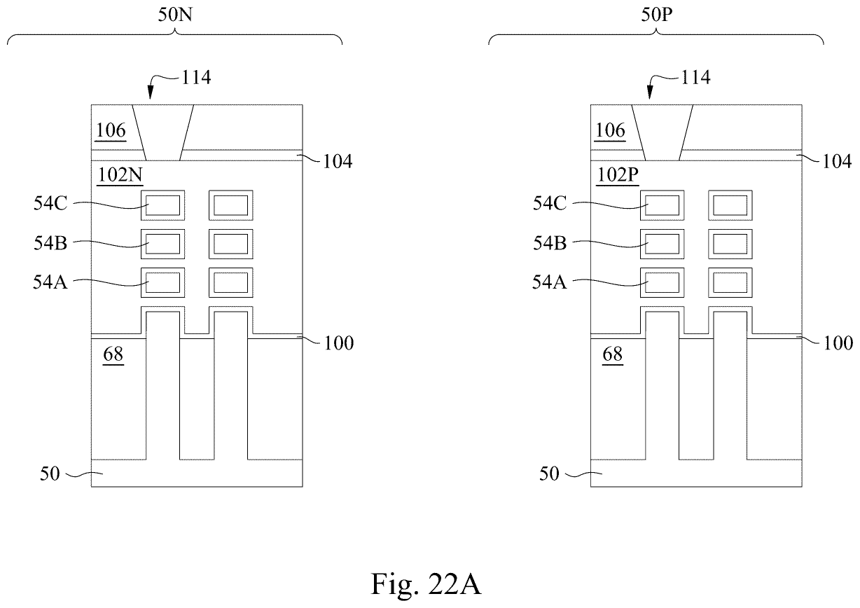

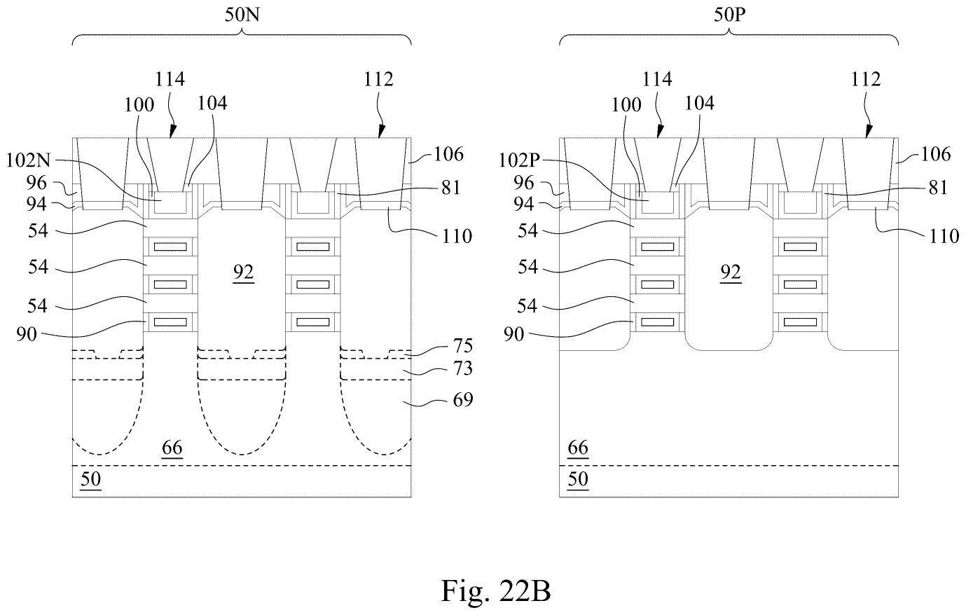

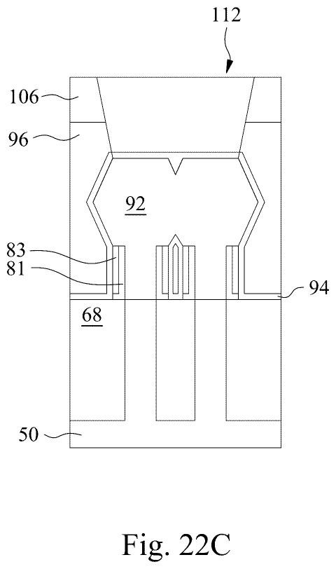

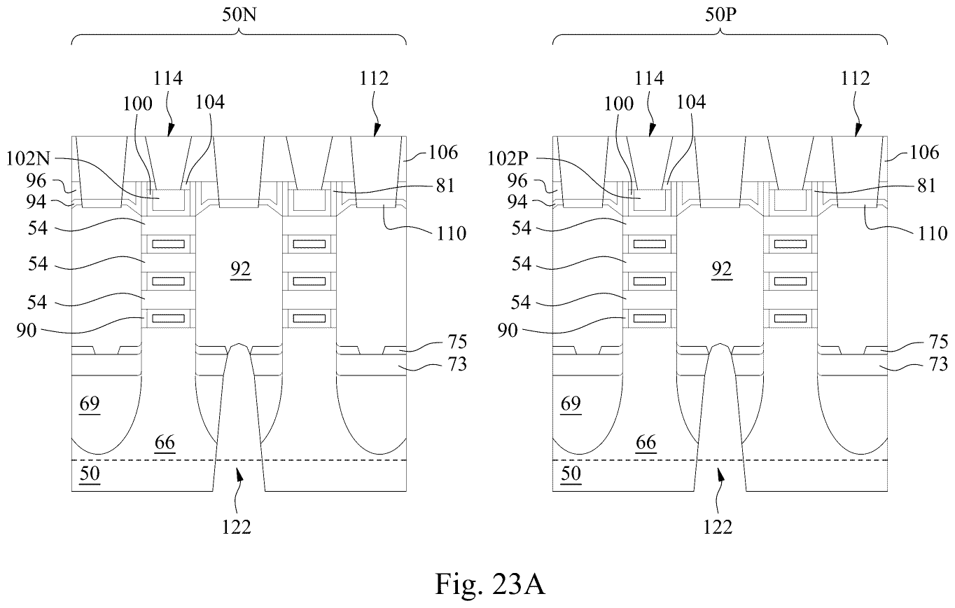

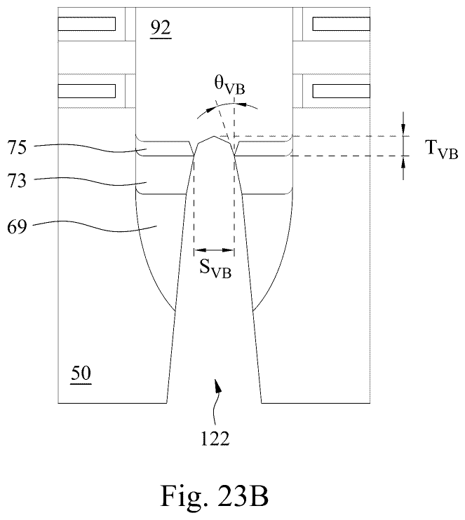

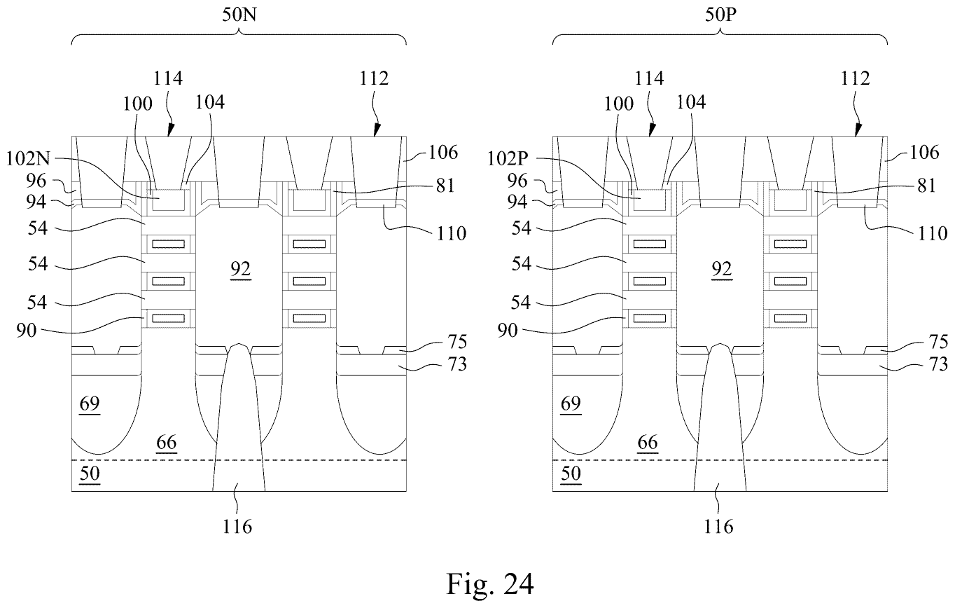

In still other embodiments, the first semiconductor layers 51 may be removed and the second semiconductor layers 53 may be patterned to form channel regions of nano-FETS in both the n-type region 50N and the p-type region 50P. In other embodiments, the second semiconductor layers 53 may be removed and the first semiconductor layers 51 may be patterned to form channel regions of nano-FETs in both the n-type region 50N and the p-type region 50P. In such embodiments, the channel regions in both the n-type region 50N and the p-type region 50P may have a same material composition (e.g., silicon, or the another semiconductor material) and be formed simultaneously. FIGS. 22A, 22B, 22C, and 24 illustrate a structure resulting from such embodiments where the channel regions in both the p-type region 50P and the n-type region 50N comprise silicon, for example.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material suitable for p-type nano-FETs, such as silicon germanium, or the like, and the second semiconductor layers 53 may be formed of a second semiconductor material suitable for n-type nano-FETs, such as silicon, silicon carbon, or the like. The multi-layer stack 64 is illustrated as having a bottommost semiconductor layer suitable for p-type nano-FETs for illustrative purposes. In some embodiments, multi-layer stack 64 may be formed such that the bottommost layer is a semiconductor layer suitable for n-type nano-FETs.

The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material in the n-type region 50N, thereby allowing the second semiconductor layers 53 to be patterned to form channel regions of n-type nano-FETs. Similarly, the second semiconductor layers 53 of the second semiconductor material may be removed without significantly removing the first semiconductor layers 51 of the first semiconductor material in the p-type region 50P, thereby allowing the first semiconductor layers 51 to be patterned to form channel regions of p-type nano-FETs.

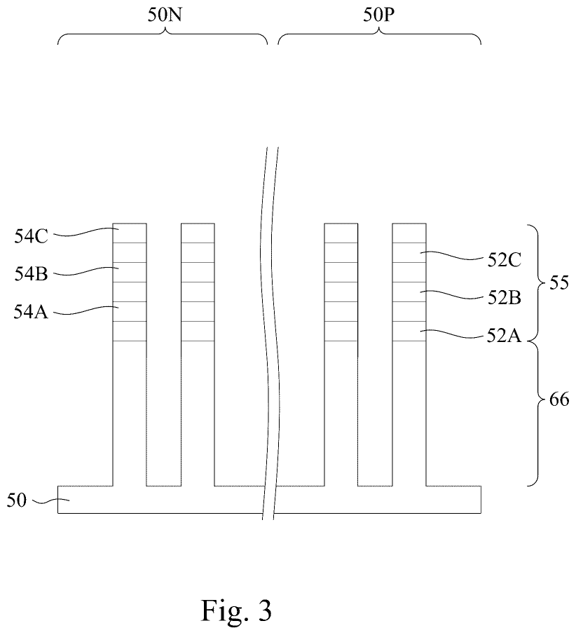

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

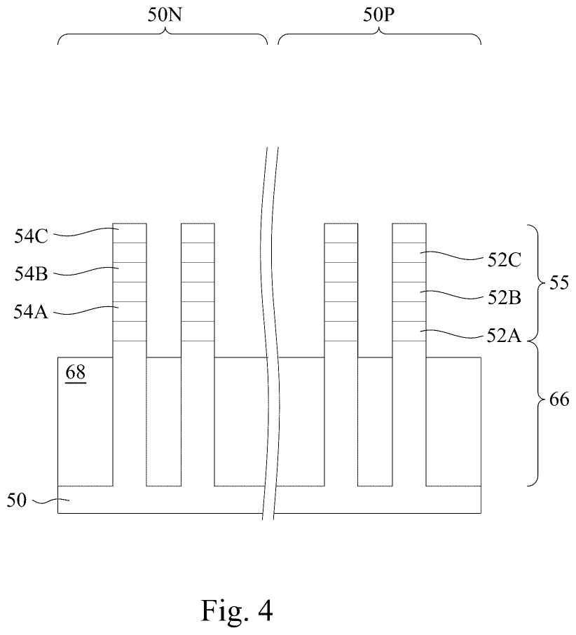

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the one or more first semiconductor layers 51 (and resulting one or more nanostructures 52) and the second one or more semiconductor layers 53 (and resulting one or more nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

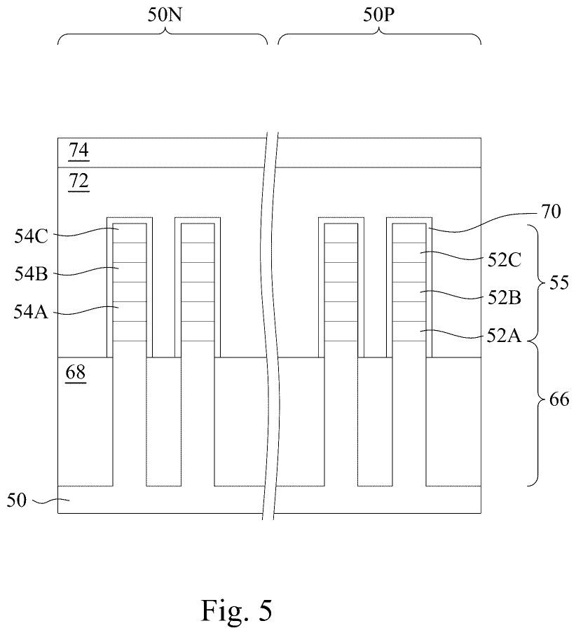

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 19C illustrate various additional steps in the manufacturing of embodiment devices. FIGS. 6A, 7A, 8A, 9A, 10A, 11A, 13A, 13C, 14A, 14C, 15A, 16A, and 19C illustrate features in either the regions 50N or the regions 50P. In FIGS. 6A and 6B, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

In FIGS. 7A and 7B, a first spacer layer 80 and a second spacer layer 82 are formed over the structures illustrated in FIGS. 6A and 6B, respectively. The first spacer layer 80 and the second spacer layer 82 will be subsequently patterned to act as spacers for forming self-aligned source/drain regions. In FIGS. 7A and 7B, the first spacer layer 80 is formed on top surfaces of the STI regions 68; top surfaces and sidewalls of the fins 66, the nanostructures 55, and the masks 78; and sidewalls of the dummy gates 76 and the dummy gate dielectric 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1×10¹⁵ atoms/cm³ to about 1×10¹⁹ atoms/cm³. An anneal may be used to repair implant damage and to activate the implanted impurities.

In FIGS. 8A and 8B, the first spacer layer 80 and the second spacer layer 82 are etched to form first spacers 81 and second spacers 83. As will be discussed in greater detail below, the first spacers 81 and the second spacers 83 act to self-aligned subsequently formed source drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 8A. Thereafter, the second spacers 83 acts as a mask while etching exposed portions of the first spacer layer 80, thereby forming first spacers 81 as illustrated in FIG. 8A.

As illustrated in FIG. 8A, the first spacers 81 and the second spacers 83 are disposed on sidewalls of the fins 66 and/or nanostructures 55. As illustrated in FIG. 8B, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy dielectric layers 60. In other embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

In FIGS. 9A through 9C, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 9A, top surfaces of the STI regions 58 may be level with bottom surfaces of the first recesses 86. In various embodiments, the fins 66 may be etched such that bottom surfaces of the first recesses 86 are disposed below the top surfaces of the STI regions 68; or the like. The first recesses 86 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

As shown in FIGS. 9B and 9C, different etch profiles may be formed in the substrate 50 according to various possible embodiments. FIG. 9B shows a shallow etch first recess 86 in substrate 50 where a pure silicon substrate is utilized below the later formed epitaxial source/drain region 92. FIG. 9C show a deep rounded first recess 86 in substrate 50, where a later formed retarding layer 73 may be used below the epitaxial source/drain region 92, according to some embodiments.

FIGS. 9D-F show different profiles for a first under-layer 69 in the first recess 86 of substrate 50 with different surface profiles for the growth, according to some embodiments. In the embodiments shown in FIGS. 9D-E, where the deep first recess 86 in substrate 50 has been utilized, a first under-layer 69 is formed on the top of the substrate 50 in the first recesses 86, prior to forming the retarding layer 73. In some embodiments the first under-layer 69 may be comprised of silicon and germanium where the ratio of silicon to germanium is described as Si₁₋ₓGeₓ where 0.0≥X≥0.4.

In some embodiments, the first under-layer 69 is formed using a CVD process with a temperatures between 400° C. and 750° C. In some embodiments, a pressure between 10 torr and 300 torr may be used during the CVD process. For example, all, or a portion of the CDV process for growing the first under-layer 69 may be performed at between 520° C. and 620° C. and with a pressure between 20 torr and 100 torr. Chemical precursors such as H₂SiCl₂ (DCS), SiH₄, Si₂H₆, GeH₄, GeCl₄, HCl, and Cl₂ may be used to control the composition of the first under-layer 69. However, any known methods may be utilized for formation of the first under-layer 69.

FIG. 9D shows a substantially flat surface profile of the first under-layer 69, according to some embodiments. FIG. 9E illustrates a rounded surface profile first under-layer 69 that is shallower on the edges closest to edges of the first recess 86, according to some embodiments. FIG. 9F illustrates a second rounded surface profile of the first under-layer 69 that is deeper on the edges and shallower towards the center of the first recess 86. For the sake or simplicity, only the shallow substrate 50 recess embodiment (as shown in FIG. 9B, with no first under-layer 69) is shown in further descriptions and figures unless necessary. However, any of the following figures as described may additionally include such elements.

In FIGS. 10A and 10B, portions of sidewalls of the layers of the multi-layer stack 64 formed of the first semiconductor materials (e.g., the first nanostructures 52) exposed by the first recesses 86 are etched to form sidewall recesses 88 in the n-type region 50N, and portions of sidewalls of the layers of the multi-layer stack 56 formed of the second semiconductor materials (e.g., the second nanostructures 54) exposed by the first recesses 86 are etched to form sidewall recesses 88 in the p-type region 50P. Although sidewalls of the first nanostructures 52 and the second nanostructures 54 in sidewall recesses 88 are illustrated as being straight in FIG. 10B, the sidewalls may be concave or convex. The sidewalls may be etched using isotropic etching processes, such as wet etching or the like. The p-type region 50P may be protected using a mask (not shown) while etchants selective to the first semiconductor materials are used to etch the first nanostructures 52 such that the second nanostructures 54 and the substrate 50 remain relatively unetched as compared to the first nanostructures 52 in the n-type region 50N. Similarly, the n-type region 50N may be protected using a mask (not shown) while etchants selective to the second semiconductor materials are used to etch the second nanostructures 54 such that the first nanostructures 52 and the substrate 50 remain relatively unetched as compared to the second nanostructures 54 in the p-type region 50P. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52 in the n-type region 50N, and a wet or dry etch process with hydrogen fluoride, another fluorine-based etchant, or the like may be used to etch sidewalls of the second nanostructures 54 in the p-type region 50P.

In FIGS. 11A-11C, first inner spacers 90 are formed in the sidewall recess 88. The first inner spacers 90 may be formed by depositing an inner spacer layer (not separately illustrated) over the structures illustrated in FIGS. 10A and 10B. The first inner spacers 90 act as isolation features between subsequently formed source/drain regions and a gate structure. As will be discussed in greater detail below, source/drain regions will be formed in the first recesses 86, while the first nanostructures 52 in the n-type region 50N and the second nanostructures 54 in the p-type region 50P will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the first inner spacers 90. Although outer sidewalls of the first inner spacers 90 are illustrated as being flush with sidewalls of the second nanostructures 54 in the n-type region 50N and flush with the sidewalls of the first nanostructures 52 in the p-type region 50P, the outer sidewalls of the first inner spacers 90 may extend beyond or be recessed from sidewalls of the second nanostructures 54 and/or the first nanostructures 52, respectively.

Moreover, although the outer sidewalls of the first inner spacers 90 are illustrated as being straight in FIG. 11B, the outer sidewalls of the first inner spacers 90 may be concave or convex. As an example, FIG. 11C illustrates an embodiment in which sidewalls of the first nanostructures 52 are concave, outer sidewalls of the first inner spacers 90 are concave, and the first inner spacers 90 are recessed from sidewalls of the second nanostructures 54 in the n-type region 50N. Also illustrated are embodiments in which sidewalls of the second nanostructures 54 are concave, outer sidewalls of the first inner spacers 90 are concave, and the first inner spacers 90 are recessed from sidewalls of the first nanostructures 52 in the p-type region 50P. The inner spacer layer may be etched by an anisotropic etching process, such as RIE, NBE, or the like. The first inner spacers 90 may be used to prevent damage to subsequently formed source/drain regions (such as the epitaxial source/drain regions 92, discussed below with respect to FIGS. 13A-13C) by subsequent etching processes, such as etching processes used to form gate structures.

A retarding layer 73 may formed, according to some embodiments. In some embodiments a retarding layer 73 may be used to retard a backside etching rate, increase the control of the etch, and limit penetration into the epitaxial source/drain region 92 where backside through silicon via (TSV) contacts are used. Accordingly, the depth of the penetration of a backside TSV into a source/drain region 92 can be limited, thereby enhancing operation and efficiency of the associated devices, and limiting manufacturing defects. Specifically, by limiting the penetration of a backside etch into the epitaxial source/drain region 92, the overall size of the epitaxial source/drain region 92 is increased, resulting in a more efficient epitaxial source/drain region 92 with lower resistivity, increased speed and performance, and a lower associated voltage drop. Accordingly, power losses, for example from thermal losses, may be reduced, overall heat generation may be reduced, and a lower power requirements may be realized. Increased production yields, lowered production costs, increased manufacturing efficiency, and smaller device sizes and thicknesses may therefore also be realized.

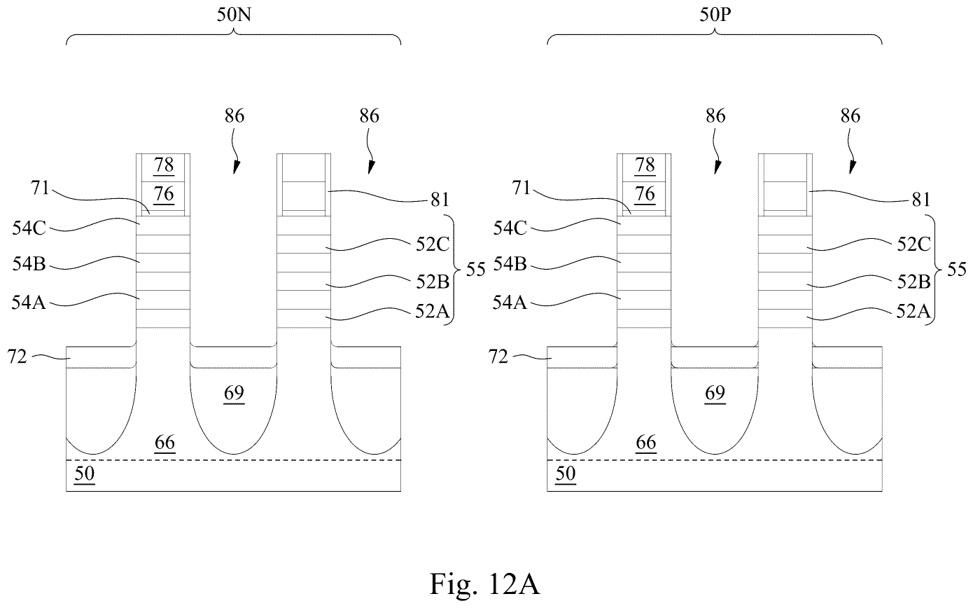

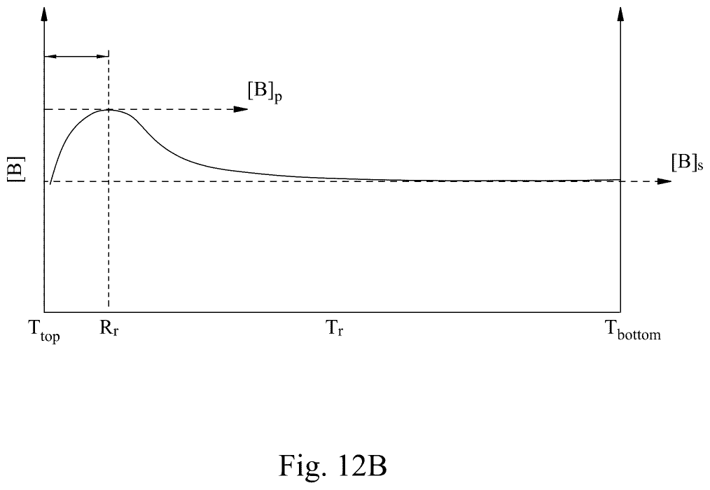

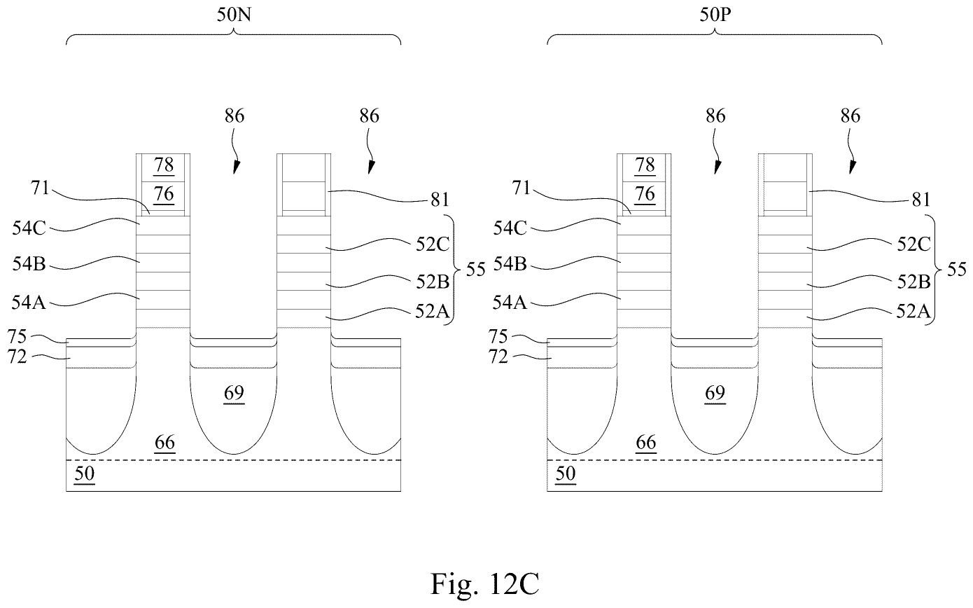

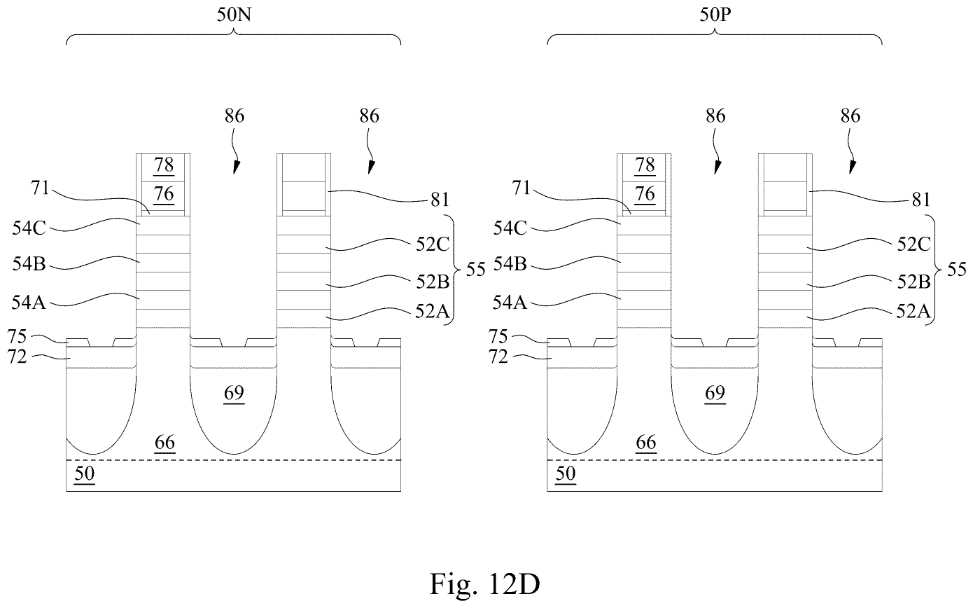

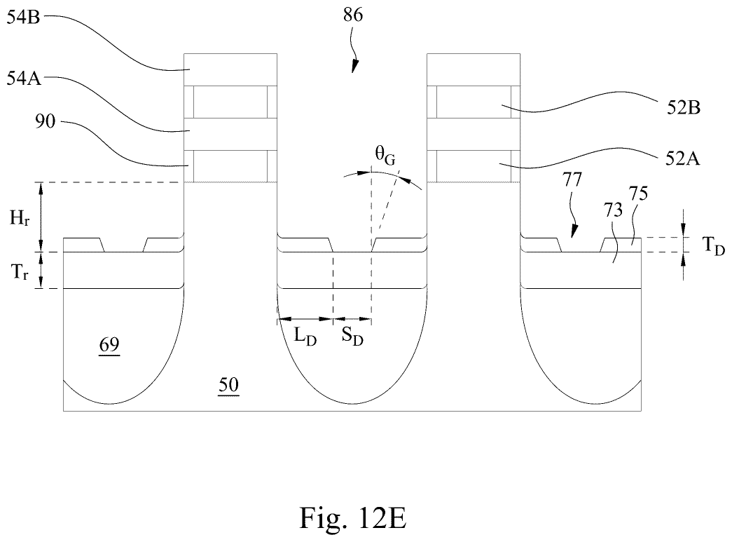

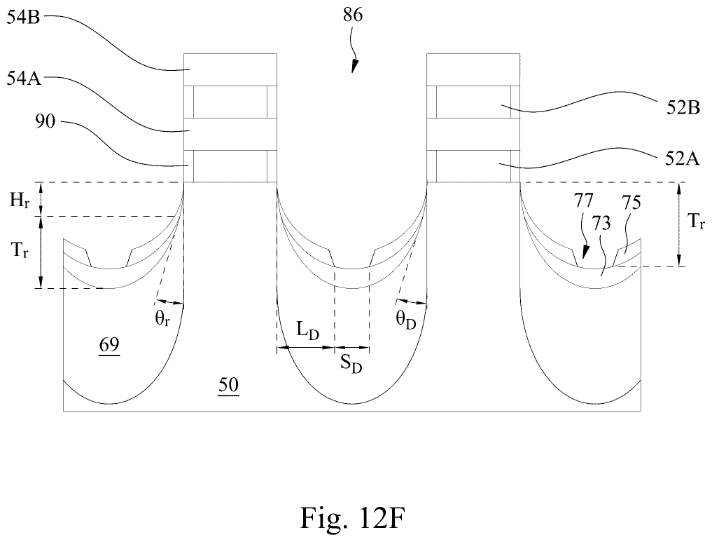

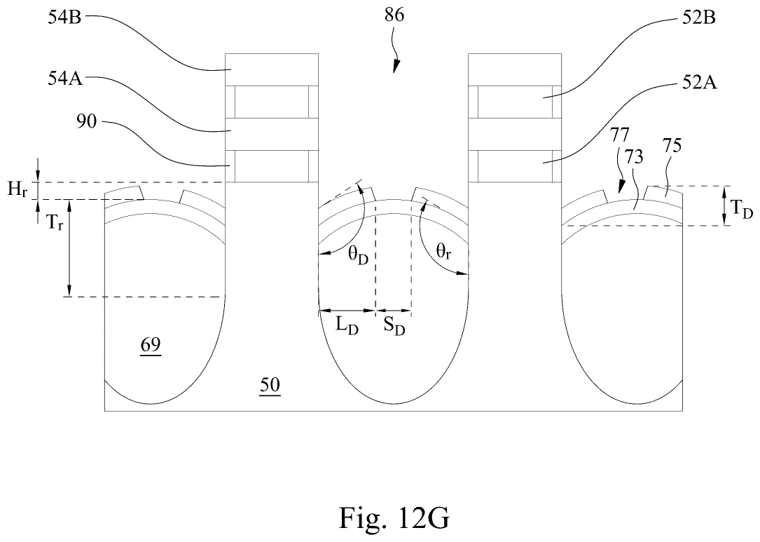

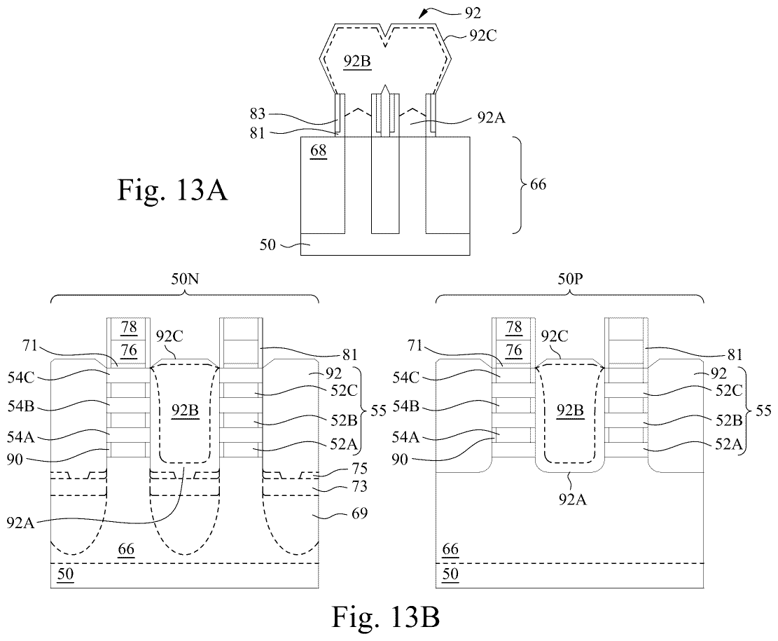

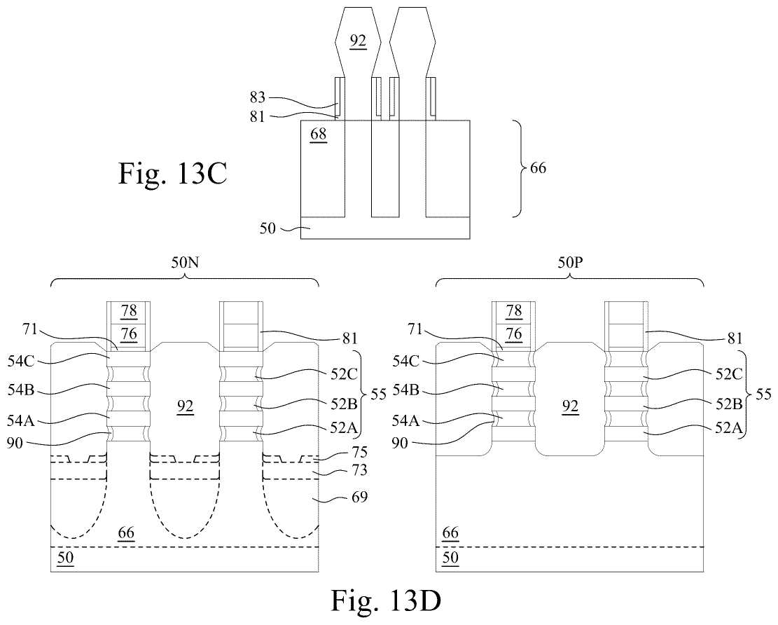

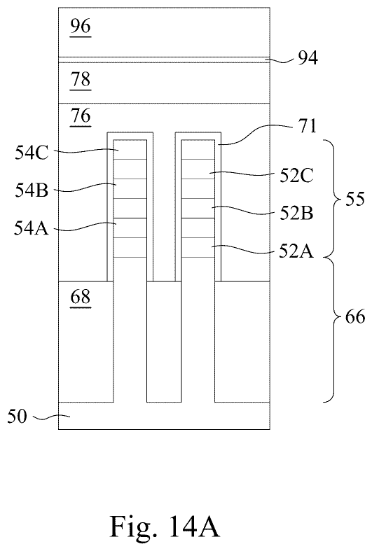

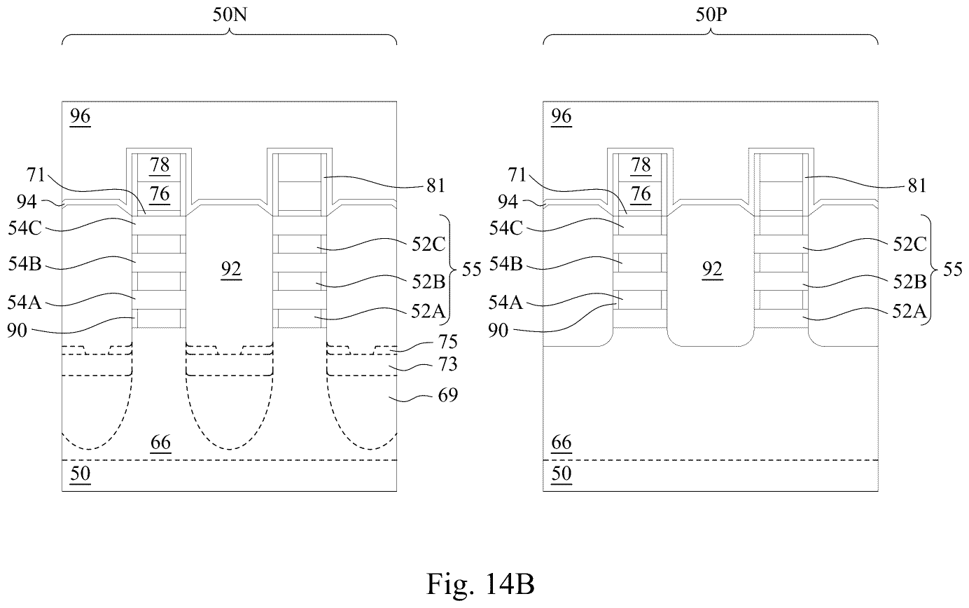

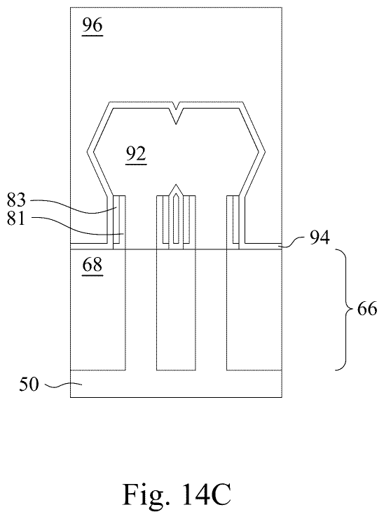

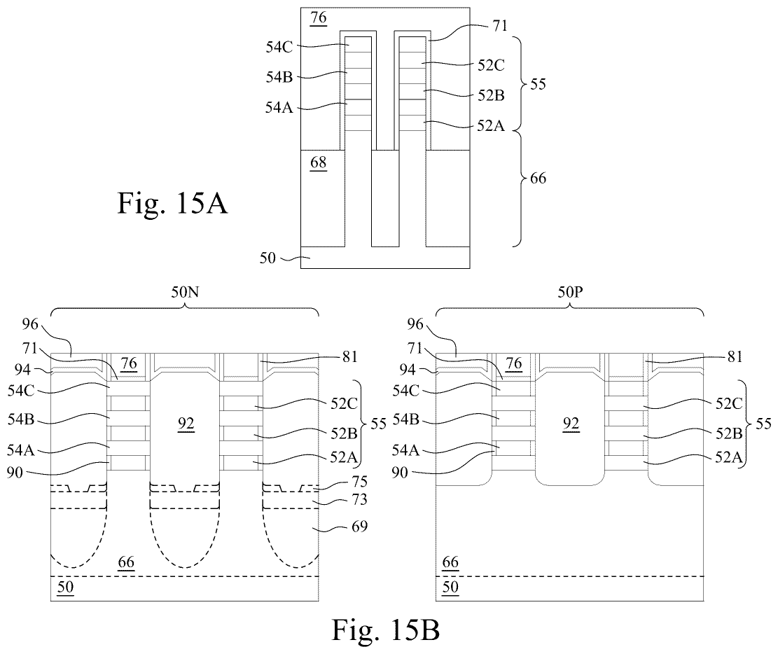

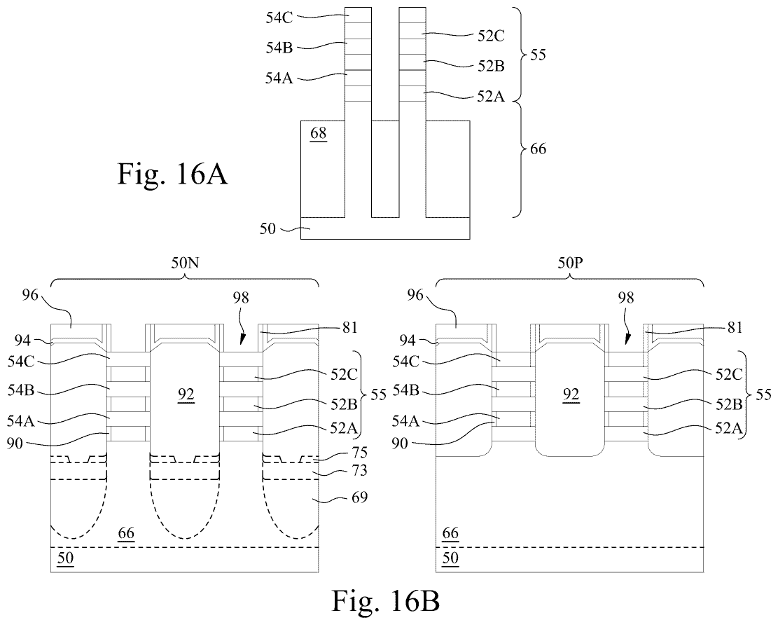

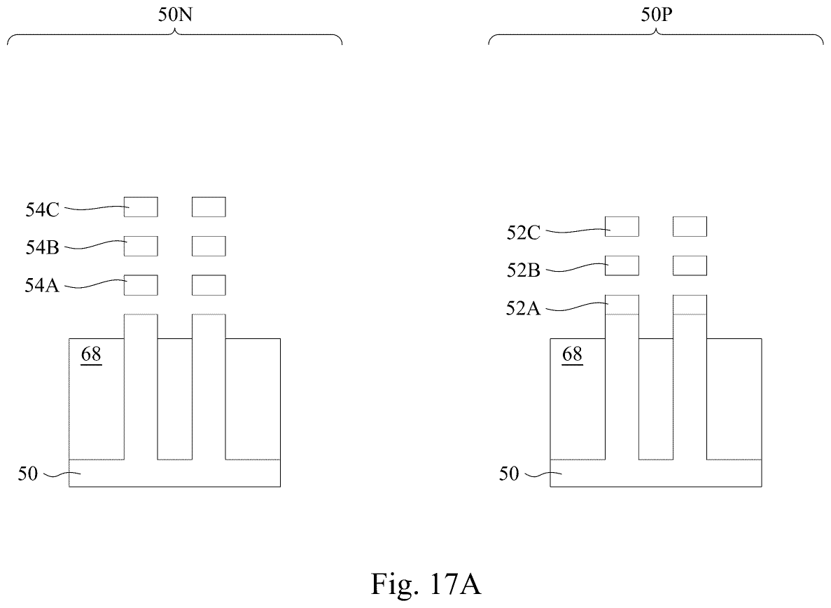

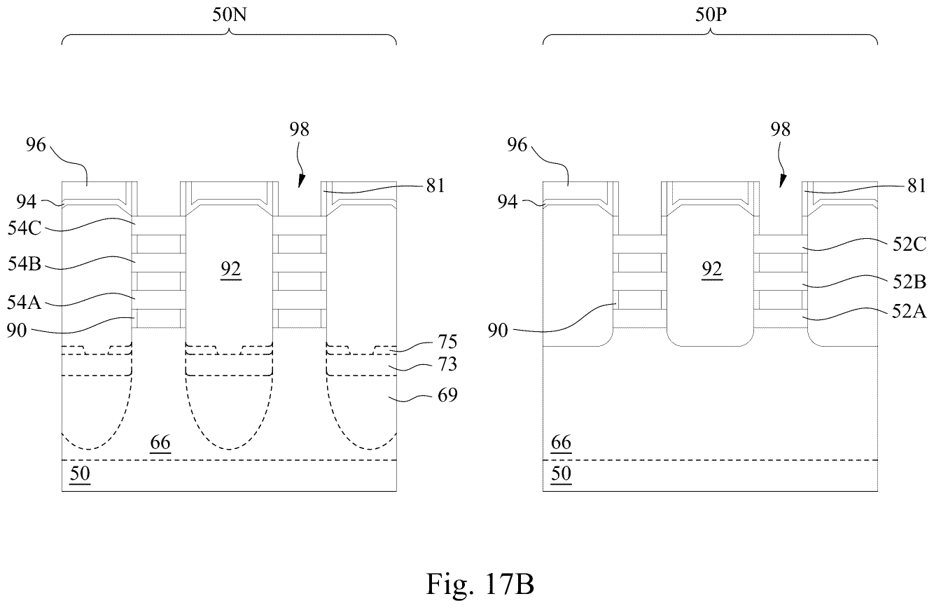

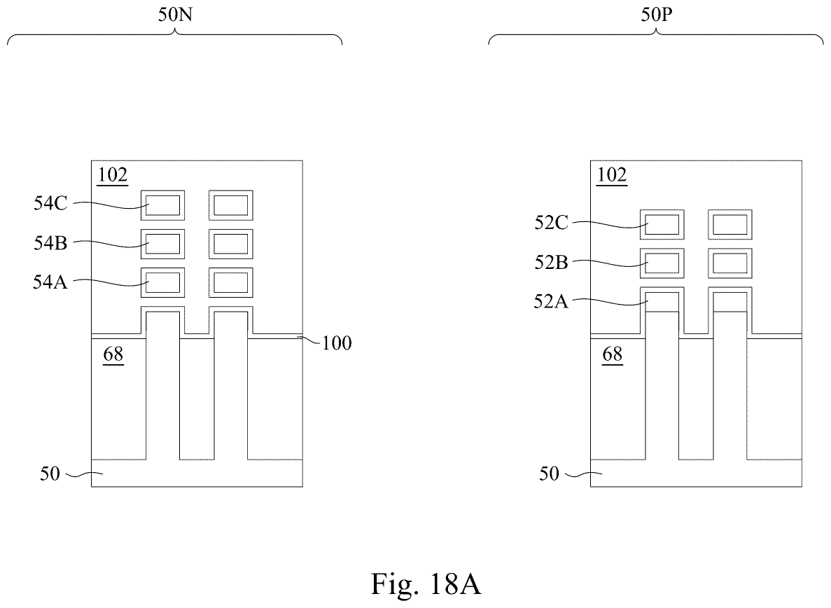

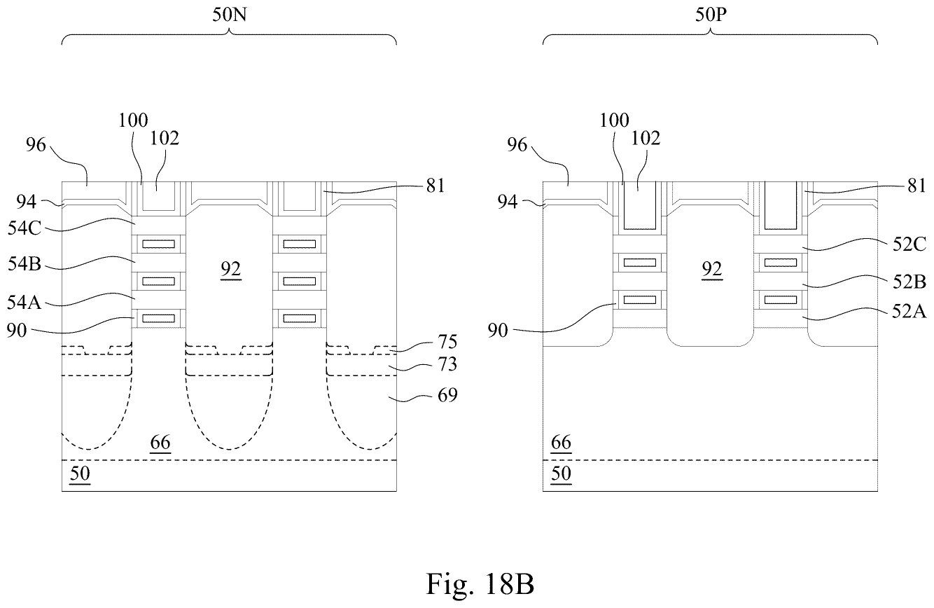

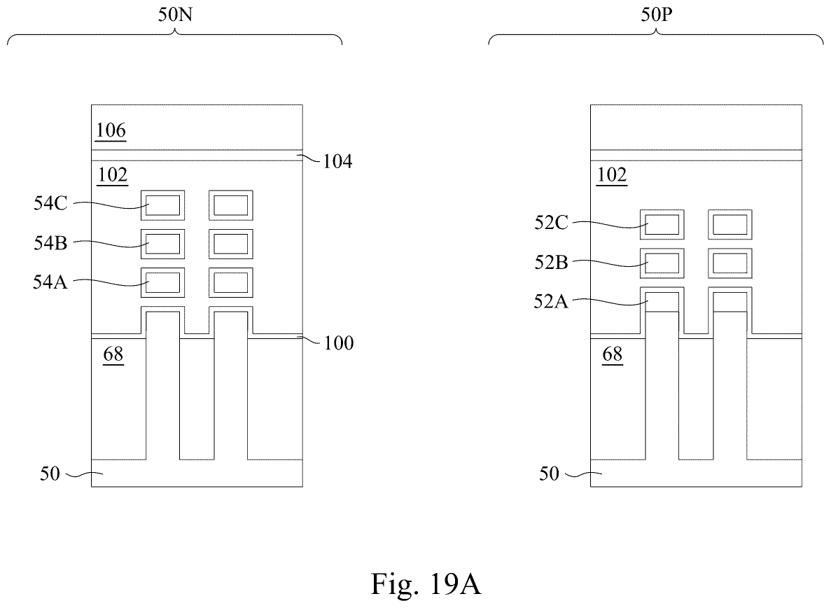

In a first embodiment, as shown in FIGS. 12A through 12E, where a deep flat etch profile in substrate 50 has been utilized, the retarding layer 73 is formed on the top of the substrate 50 in the first recesses 86. In some embodiments, the retarding layer may be comprised of silicon germanium where the ratio of silicon to germanium is described as Si₁₋ₓGeₓ where 0.0≥X≥0.4. In some embodiments the retarding layer 73 may comprise an impurity to further retard the etch rate of the substrate 50, while conforming to the later formed epitaxial source/drain region 92. For example, for the n-type region 50N where a p-type epitaxial source/drain region 92 is utilized, the retarding layer 73 may be doped with boron according to some embodiments. In some embodiments, the concentration of the boron doping ([B]) of the retarding layer 73 may be between 1×10²⁰ to 5>10²² atoms per centimeter cubed (atm/cm³).

In other embodiments, the retarding layer 73 may be comprised of silicon boride (SiB), silicon carbide (SiC), silicon oxide (SiOₓ), or silicon germanium (SiGe) doped with carbon, nitrogen, or oxygen, or another material that is capable of forming the retarding layer as a crystalline extension of the substrate to maintain the integrity of the substrate in the final product. Further the etch selectivity of the retarding layer 73 compared to silicon should be between 1.01 and 100.00.

Various process parameters significantly influence the quality and characteristics of the formation of the retarding layer 73. For example, when using CVD to form the retarding layer 73, temperature control is advantageous, as it dictates the reaction rates and crystal structure formation; precise control within a narrow range is desirable for uniformity and desired properties. Gas flow rates and composition regulate the deposition rate and chemical reactions at the substrate surface, impacting layer thickness and composition. Pressure within the reaction chamber affects gas diffusion and surface interactions, influencing layer morphology and defect density. Additionally, substrate orientation and surface preparation influence epitaxial growth by dictating nucleation sites and crystal alignment. Fine-tuning these parameters optimizes epitaxial growth.

In some embodiments, the retarding layer 73 is formed using a CVD process with a temperatures between 400° C. and 750° C. In some embodiments, a pressure between 10 torr and 300 torr may be used during the CVD process. For example, all, or a portion of the CDV process for growing the retarding layer 73 may be performed at between 520° C. and 620° C. and with a pressure between 20 torr and 100 torr. Epitaxial growth within these ranges may be accomplished without phase transformation resulting in flatter surfaces and higher quality growth layers. Chemical precursors such as H₂SiCl₂ (DCS), SiH₄, Si₂H₆, GeH₄, GeCl₄, HCl, and Cl₂ may be used to control the composition of the retarding layer 73. For a retarding layer 73 used in a p-type epitaxial source/drain region 92 (such as in n-type region 50N), a dopant precursor gas may be used and may include B₂H₆, BCl₃, and Ga(CH₃)₃. For a retarding layer 73 used in a n-type epitaxial source/drain region 92 (such as in p-type region 50P), a dopant precursor gas may include PH₃, AsH₄, and the like. However, any known methods may be utilized for formation of the retarding layer 73.

In some embodiments, the doping of the impurities in the retarding layer 73 may be a concentration gradient that varies as a function of the thickness of the retarding layer 73. FIG. 12B is an example boron doping concentration profile of the retarding layer 73, according to some embodiments. In the example concentration profile shown, the impurity is boron for a p-type source/drain region and the boron concentration may vary between a baseline boron concentration [Bₛ] and a peak boron concentration [Bₚ]. In some embodiments, the peak impurity concentration may be determined based on blanket wafer data and such that the impurity concentration will not impact the operation of the epitaxial source/drain region 92.

Tᵣ indicates the position of the relative concentration in the retarding layer with the left vertical axis at the top of the retarding layer (Tₜₒₚ), and the right vertical axis at the bottom of the retarding layer (T_{bottom}). The concentration of the impurities may be varied by controlling the flowrate of the various precursor gases, for example, as a function of time where a CVD method is used to form the retarding layer 73, according to some embodiments. The peak boron concentration [Bₚ] is reached at a depth Rᵣ of the retarding layer 73 as measured from the top of the retarding layer 73. In some embodiments, the depth Rᵣ of the peak boron concentration [Bₚ] is from 1 nm to 15 nm from the top surface of the retarding layer 73. In some embodiments, the distance from the position of the peak boron concentration [Bₚ] (Rᵣ) to T_{bottom} may be between 1 and 29 nm. In some embodiments the baseline boron concentration [Bₛ] may be between 1×10²⁰ to 2×10²² atm/cm³. In some embodiments the peak boron concentration [Bₚ] may be between 1×10²⁰ to 5×10²² atm/cm³. The ratio of peak boron concentration [Bₚ] to the baseline boron concentration [Bₛ] may be between 1.0 to 2.5.

As shown in FIG. 12C, a further dielectric layer 75 may be used to control the shape of the portion of a backside TSV etch into the source/drain region 92. In some embodiments the dielectric layer 75 may be silicon oxide, silicon nitride, silicon oxynidtride, silicon carbide, or some other dielectric material that may resist selective etching of the substrate 50. The dielectric layer 75 may be deposited on the substrate 50 and retarding layer 73, for example, by spin coating, lamination, chemical vapor deposition (CVD), atomic layer deposition (ALD), physical vapor deposition (PVD), high-density plasma chemical vapor deposition (HDPCVD), thermal oxidation, a combination thereof, and/or the like. However, any suitable materials and deposition processes may be utilized.

FIG. 12D illustrates the patterning of the dielectric layer 75, according to some embodiments. In some embodiments, the gaps 77 are formed in the dielectric layer 75 with combination of photolithography and etching processes. For example, the gaps 77 may be formed in a plasma etching process. Gaps 77 may be formed in the dielectric layer 75 when the material of the dielectric layer is not susceptible to an etching process later used to for the recess in the substrate 50, retarding layer 73, and epitaxial source/drain region 92. Gaps 77 in the dielectric layer 75 may also be formed where the dielectric layer 75 exhibits a very high etch selectivity when compared to silicon (for example, etch selectivity greater than 100). The plasma etching process may include forming a patterned mask over the dielectric layer 75 and substrate 50. The patterned mask may be a photomask that is deposited in a spin-on process and patterned by lithography (e.g., exposure and development) to define openings that expose the dielectric layer 75 in the gaps 77. The etching process etches portions of the dielectric layer 75 through the patterns (e.g., openings) in the patterned mask.

In some embodiments the etching process may be performed using a plasma dry etch process and/or a reactive ion etch (RIE). For example, a reactive ion etch using reactive gases such as CF₄, C₄F₈, CHF₃, or CH₃F which have a low reactivity to the substrate 50 material may be performed to preferentially etch through the dielectric layer 75. The etch may be controlled by varying the timing of the etching process, among other process parameters. In some embodiments, a wet etch may also be performed to cure any surface defects resulting from a dry etching process. In some embodiments, the RIE uses an argon-based plasma, an oxygen-based plasma, a nitrogen-based plasma, or the like. However, any suitable method of patterning the gaps 77 in the dielectric layer 75 may be utilized.

FIG. 12E is an enlarged portion of the n-type region 50N shown in FIG. 12D, according to some embodiments. In some embodiments, the thickness Tᵣ of the retarding layer 73 may be between 1 nm and 30 nm (1 nm≤T_{R}≤30 nm). In some embodiments the topmost portion of the retarding layer 73, as referenced to the bottommost portion the bottom gate electrode 102, may be at a height Hᵣ of between −15 nm and +15 nm (−15 nm≤Hᵣ≤+15 nm). A positive value of the height Hᵣ of the retarding layer 73 (Hᵣ>0) indicates that the topmost portion of the retarding layer 73 is above the topmost portion of the substrate 50. A positive value above the bottommost portion of the bottom gate electrode may be used when all of the available channels are not necessary or desired for a specific nano-FET in a specific design implementation, thereby adding flexibility to the design. A negative value of a height Hᵣ of the retarding layer 73 (Hᵣ<0) indicates that the topmost portion of the retarding layer 73 is below the topmost portion of the substrate 50. A thickness (T_{D}) of the dielectric layer 75 may be from 1 nm to 10 nm (1 nm≤T_{D}≤10 nm), according to some embodiments. In some embodiments, a ratio of the thickness (T_{D}) of the dielectric layer 75 to the thickness Tᵣ of the retarding layer 73 may be between 1 to 20. In some embodiments, a width (S_{D}) of the gap 77 in the dielectric layer 75 at the interface between the dielectric layer 75 and the retarding layer 73 may be from 1 nm to 20 nm (1 nm≤S_{D}≤20 nm). In some embodiments, the length (L_{D}) of the dielectric layer 75 from a sidewall of the first recess 86 to the smallest portion of the gap 77 in the dielectric layer 75 may be from 1 nm to 10 nm (1 nm≤L_{D}≤10 nm). In some embodiments, a ratio of the width (S_{D}) of the gap 77 in the dielectric layer 75 to the length (L_{D}) of the dielectric layer 75 from a sidewall of the first recess 86 to the smallest portion of the gap 77 in the dielectric layer 75 may be between 1 to 10. In some embodiments, an angle (θ_{G}) between a line drawn perpendicular to the major axis of the substrate 50 and the angle of the etched sidewalls of the dielectric layer 75 at the gap 77 may be from 10 degrees to 150 degrees (10°≤θ_{D}≤150°).

FIGS. 12F and 12G illustrate further embodiments of the formation of the retarding layer 73 and dielectric layer 75 where a substantially curved etch in the substrate is utilized. The retarding layer 73 and dielectric layer 75 may be formed using processes similar to those described above in relation to FIGS. 12A through 12E, and only the shape is substantially different.

FIG. 12F illustrates an embodiment where a concave bottom of first recess 86 is formed in substrate 50, resulting in curved down retarding layers 73 and dielectric layers 75. In some embodiments, the thickness Tᵣ of the retarding layer 73 may be between 1 nm and 30 nm (1 nm≤T_{R}≤30 nm). In some embodiments the topmost portion of the retarding layer 73, as referenced to the topmost portion the substrate 50, may be at a height Hᵣ of between −15 nm and +15 nm (−15 nm≤Hᵣ≤+15 nm). A positive value of the height Hᵣ of the retarding layer 73 (Hᵣ>0) indicates that the topmost portion of the retarding layer 73 is above the topmost portion of the substrate 50. A negative value of a height Hᵣ of the retarding layer 73 (Hᵣ<0) indicates that the topmost portion of the retarding layer 73 is below the topmost portion of the substrate 50. In some embodiments, an angle (θᵣ) between a line drawn perpendicular to the major axis of the substrate 50 and the surface of the retarding layer 73 at the point closes to the wall of first recess 86 may be from 5 degrees to 120 degrees (5°≤θᵣ≤120°).

A thickness (T_{D}) of the dielectric layer 75 may be from 1 nm to 10 nm (1 nm≤T_{D}≤10 nm), according to some embodiments. In some embodiments, a width (S_{D}) of the gap 77 in the dielectric layer 75 at the interface between the dielectric layer 75 and the retarding layer 73 may be from 1 nm to 20 nm (1 nm≤S_{D}≤20 nm). In some embodiments, the horizontal length (L_{D}) of the dielectric layer 75 from a sidewall of the first recess 86 to the smallest portion of the gap 77 in the dielectric layer 75 may be from 1 nm to 10 nm (1 nm≤L_{D}≤10 nm). In some embodiments, an angle (θ_{D}) between a line drawn perpendicular to the major axis of the substrate 50 and a tangent of the dielectric layer 75 at the interface of the sidewalls of first recess 86 may be from 5 degrees to 120 degrees (5°≤θ_{D}≤120°). As should be understood, FIG. 12G represents a possible cross-sectional view where the angle (θ_{D}) between a line drawn perpendicular to the major axis of the substrate 50 and a tangent of the dielectric layer 75 at the interface of the sidewalls of recess 86 is less than 90 degrees.

FIG. 12G illustrates an embodiment where a convex bottom of first recess 86 is formed in substrate 50, resulting in curved upwards retarding layers 73 and dielectric layers 75. In some embodiments, the thickness Tᵣ of the retarding layer 73 may be between 1 nm and 30 nm (1 nm≤T_{R}≤30 nm). In some embodiments the topmost portion of the retarding layer 73, as referenced to the topmost portion the substrate 50, may be at a height Hᵣ of between −15 nm and +15 nm (−15 nm≤Hᵣ≤+15 nm). A positive value of the height Hᵣ of the retarding layer 73 (Hᵣ>0) indicates that the topmost portion of the retarding layer 73 is above the topmost portion of the substrate 50. A negative value of a height Hᵣ of the retarding layer 73 (Hᵣ<0) indicates that the topmost portion of the retarding layer 73 is below the topmost portion of the substrate 50. In some embodiments, an angle (θᵣ) between a line drawn perpendicular to the major axis of the substrate 50 and the surface of the retarding layer 73 at the point closes to the wall of first recess 86 may be from 5 degrees to 120 degrees (5°≤θᵣ≤120°).

A thickness (T_{D}) of the dielectric layer 75 may be from 1 nm to 10 nm (1 nm≤T_{D}≤10 nm), according to some embodiments. In some embodiments, a width (S_{D}) of the gap 77 in the dielectric layer 75 at the interface between the dielectric layer 75 and the retarding layer 73 may be from 1 nm to 20 nm (1 nm≤S_{D}≤20 nm). In some embodiments, the horizontal length (L_{D}) of the dielectric layer 75 from a sidewall of the first recess 86 to the smallest portion of the gap 77 in the dielectric layer 75 may be from 1 nm to 10 nm (1 nm≤L_{D}≤10 nm). In some embodiments, an angle (θ_{D}) between a line drawn perpendicular to the major axis of the substrate 50 and a tangent of the dielectric layer 75 at the interface of the sidewalls of first recess 86 may be from 5 degrees to 120 degrees (5°≤θ_{D}≤120°). As should be understood, FIG. 12G represents a possible cross-sectional view where the angle (θ_{D}) between a line drawn perpendicular to the major axis of the substrate 50 and a tangent of the dielectric layer 75 at the interface of the sidewalls of recess 86 is less than 90 degrees.

For the sake of simplicity of illustration, FIGS. 13A through 22C are illustrated based on the shallow etch of substrate 50 as shown in FIG. 9B and without the retarding layer 73 and/or dielectric layer 75. However, it should be noted that each of the possible embodiments shown in FIGS. 9A-9F and 12A-12G may be included in FIGS. 13B through 22B as appropriate. Dotted lines have been added in the appropriate position to indicate if retarding layer 73 and the dielectric layer 75 are included under the central epitaxial source/drain region 92.

In FIGS. 13A-13C, epitaxial source/drain regions 92 are formed in the first recesses 86. In some embodiments, the source/drain regions 92 may exert stress on the second nanostructures 54 in the n-type region 50N and on the first nanostructures 52 in the p-type region 50P, thereby improving performance. As illustrated in FIG. 13B, the epitaxial source/drain regions 92 are formed in the first recesses 86 such that each dummy gate 76 is disposed between respective neighboring pairs of the epitaxial source/drain regions 92. In some embodiments, the first spacers 81 are used to separate the epitaxial source/drain regions 92 from the dummy gates 76 and the first inner spacers 90 are used to separate the epitaxial source/drain regions 92 from the nanostructures 55 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the first nanostructures 52 are silicon germanium, the epitaxial source/drain regions 92 may comprise materials exerting a compressive strain on the first nanostructures 52, such as silicon-germanium, boron doped silicon-germanium, germanium, germanium tin, or the like. The epitaxial source/drain regions 92 may also have surfaces raised from respective surfaces of the multi-layer stack 56 and may have facets.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 13A. In other embodiments, adjacent epitaxial source/drain regions 92 remain separated after the epitaxy process is completed as illustrated by FIG. 13C. In the embodiments illustrated in FIGS. 13A and 13C, the first spacers 81 may be formed to a top surface of the STI regions 68 thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI region 58.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

FIG. 13D illustrates an embodiment in which sidewalls of the first nanostructures 52 in the n-type region 50N and sidewalls of the second nanostructures 54 in the p-type region 50P are concave, outer sidewalls of the first inner spacers 90 are concave, and the first inner spacers 90 are recessed from sidewalls of the second nanostructures 54 and the first nanostructures 52, respectively. As illustrated in FIG. 12D, the epitaxial source/drain regions 92 may be formed in contact with the first inner spacers 90 and may extend past sidewalls of the second nanostructures 54 in the n-type region 50N and past sidewalls of the first nanostructures 52 in the p-type region 50P.

In FIGS. 14A-14C, a first interlayer dielectric (ILD) 96 is deposited over the structure illustrated in FIGS. 6A, 13B, and 13A (the processes of FIGS. 7A-13D do not substantially alter the cross-section illustrated in FIGS. 6A), respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the first spacers 81. The CESL 94 may comprise a dielectric material, such as, silicon nitride, silicon oxide, silicon oxynitride, or the like, having a different etch rate than the material of the overlying first ILD 96.

In FIGS. 15A and 15B, a planarization process, such as a CMP, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level within process variations. Accordingly, the top surfaces of the dummy gates 72 are exposed through the first ILD 96. In some embodiments, the masks 78 may remain, in which case the planarization process levels the top surface of the first ILD 96 with top surface of the masks 78 and the first spacers 81.

In FIGS. 16A and 16B, the dummy gates 76, and the masks 78 if present, are removed in one or more etching steps, so that second recesses 98 are formed. Portions of the dummy dielectric layers 60 in the second recesses 98 are also be removed. In some embodiments, the dummy gates 76 and the dummy dielectric layers 60 are removed by an anisotropic dry etch process. For example, the etching process may include a dry etch process using reaction gas(es) that selectively etch the dummy gates 76 at a faster rate than the first ILD 96 or the first spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy dielectric layers 60 may be used as etch stop layers when the dummy gates 76 are etched. The dummy dielectric layers 60 may then be removed after the removal of the dummy gates 76.

In FIGS. 17A and 17B, the first nanostructures 52 in the n-type region 50N and the second nanostructures 54 in the p-type region 50P are removed extending the second recesses 98. The first nanostructures 52 may be removed by forming a mask (not shown) over the p-type region 50P and performing an isotropic etching process such as wet etching or the like using etchants which are selective to the materials of the first nanostructures 52, while the second nanostructures 54, the substrate 50, the STI regions 58 remain relatively unetched as compared to the first nanostructures 52. In embodiments in which the first nanostructures 52 include, e.g., SiGe, and the second nanostructures 54A-54C include, e.g., Si or SiC, tetramethylammonium hydroxide (TMAH), ammonium hydroxide (NH₄OH), or the like may be used to remove the first nanostructures 52 in the n-type region 50N.

The second nanostructures 54 in the p-type region 50P may be removed by forming a mask (not shown) over the n-type region 50N and performing an isotropic etching process such as wet etching or the like using etchants which are selective to the materials of the second nanostructures 54, while the first nanostructures 52, the substrate 50, the STI regions 58 remain relatively unetched as compared to the second nanostructures 54. In embodiments in which the second nanostructures 54 include, e.g., SiGe, and the first nanostructures 52 include, e.g., Si or SiC, hydrogen fluoride, another fluorine-based etchant, or the like may be used to remove the second nanostructures 54 in the p-type region 50P.

In other embodiments, the channel regions in the n-type region 50N and the p-type region 50P may be formed simultaneously, for example by removing the first nanostructures 52 in both the n-type region 50N and the p-type region 50P or by removing the second nanostructures 54 in both the n-type region 50N and the p-type region 50P. In such embodiments, channel regions of n-type nano-FETs and p-type nano-FETS may have a same material composition, such as silicon, silicon germanium, or the like. FIGS. 22A, 22B, and 22C illustrate a structure resulting from such embodiments where the channel regions in both the p-type region 50P and the n-type region 50N are provided by the second nanostructures 54 and comprise silicon, for example.

In FIGS. 18A and 18B, gate dielectric layers 100 and gate electrodes 102 are formed for replacement gates. The gate dielectric layers 100 are deposited conformally in the second recesses 98. In the n-type region 50N, the gate dielectric layers 100 may be formed on top surfaces and sidewalls of the substrate 50 and on top surfaces, sidewalls, and bottom surfaces of the second nanostructures 54, and in the p-type region 50P, the gate dielectric layers 100 may be formed on top surfaces and sidewalls of the substrate 50 and on top surfaces, sidewalls, and bottom surfaces of the first nanostructures 52. The gate dielectric layers 100 may also be deposited on top surfaces of the first ILD 96, the CESL 94, the first spacers 81, and the STI regions 58.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 18A and 18B, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

In FIGS. 19A-19C, the gate structure (including the gate dielectric layers 100 and the corresponding overlying gate electrodes 102) is recessed, so that a recess is formed directly over the gate structure and between opposing portions of first spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 21A and 21B) penetrate through the gate mask 104 to contact the top surface of the recessed gate electrodes 102.

As further illustrated by FIGS. 19A-19C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

In FIGS. 20A-20C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second

ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIG. 20B illustrates the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts. After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

Next, in FIGS. 21A-C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer 114 and a conductive material 118, and is electrically coupled to the underlying conductive feature (e.g., gate structure 102 and/or silicide region 110 in the illustrated embodiment). The contacts 114 are electrically coupled to the gate structure 102 and may be referred to as gate contacts, and the contacts 112 are electrically coupled to the silicide regions 110 and may be referred to as source/drain contacts. The barrier layer 114 may include titanium, titanium nitride, tantalum, tantalum nitride, or the like. The conductive material 118 may be copper, a copper alloy, silver, gold, tungsten, cobalt, aluminum, nickel, or the like. A planarization process, such as a CMP, may be performed to remove excess material from a surface of the second ILD 106.

FIGS. 22A-C illustrate cross-sectional views of a device according to some alternative embodiments. FIG. 22A illustrates reference cross-section A-A′ illustrated in FIG. 1. FIG. 22B illustrates reference cross-section B-B′ illustrated in FIG. 1. FIG. 22C illustrates reference cross-section C-C′ illustrated in FIG. 1. In FIGS. 22A-22C, like reference numerals indicate like elements formed by like processes as the structure of FIGS. 23A-22C. However, in FIGS. 22A-C, channel regions in the n-type region 50N and the p-type region 50P comprise a same material. For example, the second nanostructures 54, which comprise silicon, provide channel regions for p-type nano-FETs in the p-type region 50P and for n-type nano-FETs in the n-type region 50N. The structure of FIGS. 22A-22C may be formed, for example, by removing the first nanostructures 52 from both the p-type region 50P and the n-type region 50N simultaneously; depositing the gate dielectrics layers 100 and the gate electrodes 102P (e.g., gate electrode suitable for a p-type nano-FET) around the second nanostructures 54 in the p-type region 50P; and depositing the gate dielectrics layers 100 and the gate electrodes 102N (e.g., a gate electrode suitable for a n-type nano-FET) around the second nanostructures 54 in the n-type region 50N. In such embodiments, materials of the epitaxial source/drain regions 92 may be different in the n-type region 50N compared to the p-type region 50P as explained above.

Where backside TSVs 116 are utilized to provide further connections to the epitaxial source/drain region 92, the alternative etching profiles of substrate 50 and first under-layer 69 as shown in FIGS. 9B-9F, as well as the retarding layer 73 and/or dielectric layer 75 may be included in the structure. TSVs 116 are formed to connect the epitaxial source/drain regions 92 to external connectors (not shown). Any suitable methods may be used for forming and patterning the TSVs 116, external connectors, and further dielectric materials and metallization materials that may be included on the backside in some embodiments. For the sake of simplicity, only one backside TSV 116 is shown formed in each of the n-type region 50N and p-type region 50P (FIG. 24). However, no limitation on the number of TSVs 116 that may be created to connect to various epitaxial source/drain regions 92 are intended.

FIG. 23A illustrates the formation of TSV openings 122, according to some embodiments. At any desired point in the manufacturing process, but after formation of the retarding layer 73 and/or dielectric layer 75, the TSVs 116 may be formed within the substrate 50 in order to provide electrical connectivity from epitaxial source/drain regions 92 to a back side of the substrate 50. In an embodiment the TSVs 116 may be formed by initially forming through silicon via (TSV) openings 122 into the substrate 50 prior to forming any alternating layers of dielectric material and conductive materials. The TSV openings may be formed by applying and developing a suitable photoresist, and removing portions of the underlying materials that are exposed to a desired depth.

In some embodiments, a reactive ion etch (RIE) may be performed using gases such as SF₆ or NF₃ to preferentially etch into the substrate 50. The depth of the etch may be controlled by varying the timing of the etching process, among other process parameters. Because of the impurities included in the retarding layer 73, the etch rate of the RIE will be slowed when the retarding layer is exposed by the etch, allowing greater control of the depth of the TSV openings formed into the epitaxial source/drain regions 92.

In embodiments further including a dielectric layer 75 between the retarding layer 73 and epitaxial source/drain regions 92, such as shown in FIG. 23A, the RIE may uses gases that will exhibit a high selectivity for etching the substrate 50, retarding layer 73 (at a slower rate than the substrate 50), and epitaxial source/drain regions 92, as opposed to the dielectric layer 75. Accordingly, as shown in further detail in FIG. 23B, illustrating an enlarged portion of FIG. 23A, the sidewalls of the etch in the substrate and/or epitaxial source/drain regions 92 may be steeper than the sidewalls of the etched sidewalls of the retarding layer 73. To be specific the angles (θ_{VB}) of the sidewall of the TSV opening 122 in the substrate 50 and/or epitaxial source/drain regions 92 are smaller than the angle (θ_{VB}) of the sidewall of the TSV opening 122 through the retarding layer 73.

Accordingly, the depth of the penetration (T_{VB}) and horizontal width (S_{VB}) of the etch of a backside TSVs 116 into a source/drain region 92 can be limited. In some embodiments, the depth of the penetration (T_{VB}) of the etch into the epitaxial source/drain regions 92 may be from +5 nm to +15 nm (5 nm≤T_{VB}≤15 nm). In some embodiments, the horizontal width (S_{VB}) of the etch into the epitaxial source/drain regions 92 may from approximately 0 nm to +10 nm (0 nm≤S_{VB}≤10 nm). Accordingly defects in and reduced conductivity of the epitaxial source/drain regions 92 can be minimized, enhancing operation and efficiency of the associated devices, and limiting manufacturing defects. Increased production yields, lowered production costs, increased manufacturing efficiency, and smaller device sizes and thicknesses may therefore be realized.

FIG. 24 illustrates the completion of the TSVs 116, according to some embodiments. Once the TSV openings 122 have been formed within the substrate 50, the TSV openings 122 may be lined with a liner (not shown). The liner may be, e.g., an oxide formed from tetraethylorthosilicate (TEOS) or silicon nitride, although any suitable dielectric material may be used. The liner may be formed using a plasma enhanced chemical vapor deposition (PECVD) process, although other suitable processes, such as physical vapor deposition or a thermal process, may be used.

Once the liner has been formed along the sidewalls and bottom of the TSV openings, a barrier layer (not shown) may be formed and the remainder of the TSV openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer, filling and overfilling the TSV openings. Once the TSV openings have been filled, excess liner, barrier layer, seed layer, and conductive material outside of the TSV openings may be removed through a planarization process such as chemical mechanical polishing (CMP), although any suitable removal process may be used.

Once the TSV openings 122 have been filled, the substrate may be thinned. In an embodiment the substrate 50 may be thinned using, e.g., a chemical mechanical polishing process, a grinding process, or the like. Further, once exposed, the TSVs 116 may be recessed using, e.g., one or more etching processes, such as a wet etch process in order to recess the substrate 50 so that the TSVs 116 extend out of the substrate 50.

In an embodiment external connectors (not shown) may be placed on the substrate 50 in electrical connection with the TSVs 116 and may be, e.g., a ball grid array (BGA) which comprises a eutectic material such as solder, although any suitable materials may be used. Optionally, an underbump metallization or additional metallization layers (not shown) and dialectic layers (not shown) may be utilized between the substrate 50 and the external connectors. In an embodiment in which the external connectors include are solder bumps, the external connectors may be formed using a ball drop method, such as a direct ball drop process. In another embodiment, the solder bumps may be formed by initially forming a layer of tin through any suitable method such as evaporation, electroplating, printing, solder transfer, and then performing a reflow in order to shape the material into the desired bump shape. Once the external connectors have been formed, a test may be performed to ensure that the structure is suitable for further processing.

Embodiments may achieve advantages. For example, defects in and reduced conductivity of the epitaxial source/drain regions 92 can be minimized, enhancing operation and efficiency of the associated devices, and limiting manufacturing defects. Increased production yields, lowered production costs, increased manufacturing efficiency, and smaller device sizes and thicknesses may therefore be realized.

In a first embodiment, a semiconductor device is provided, including: a substrate; a source/drain region; a retarding layer between the substrate and the source/drain region that has a slower etch rate when exposed to an etch than does the substrate and the source/drain region; and the through silicon via (TSV) electrically connecting the source/drain region to a backside of the semiconductor device, where the TSV penetrates through the substrate, the retarding layer, and a portion of the source/drain region.

In some embodiments, the semiconductor device further includes a dielectric layer between the retarding layer and the source/drain region, where the TSV further penetrates through a gap in the dielectric layer. In some embodiments, the dielectric layer is between 1 nm and 10 nm thick, a ratio of a thickness of the dielectric layer to the thickness of the retarding layer is between 1.0 and 20.0, the dielectric layer has a gap located towards the center of the dielectric layer spanning from 1 nm to 20 nm, and where a ratio between a distance the gap spans and a distance from an outside edge of the dielectric to a closest gap sidewall is between 1 and 10. In some embodiments, the retarding layer is doped with an impurity having a ratio between a peak concentration and a baseline concentration between 1.0 to 2.5. In some embodiments, the impurity concentration is a gradient starting at a baseline concentration at a top surface of the retarding layer, increasing to a peak concentration from 1 nm to 15 nm below the top surface of the retarding layer, and decreasing back towards the baseline concentration at a bottom surface of the retarding layer. In some embodiments, the semiconductor device is a n-type field effect transistor, the substrate includes silicon, the retarding layer includes Si₁₋ₓGeₓ where 0.0≤X≤0.4, the source/drain region is a p-type material, and the impurity is boron. In some embodiments, a top surface of the retarding layer is between 15 nm below a topmost surface of the substrate to 15 nm above the topmost surface of the substrate, and the retarding layer is between 1 nm and 30 nm thick. In some embodiments, the retarding layer is flat within process parameters across a width of the source/drain region. In some embodiments, the retarding layer is curved across a width of the source/drain region, and where an angle between a tangent of a topmost surface of the retarding layer at an interface of a trench enclosing the source/drain region and an imaginary line perpendicular to the major plane of the semiconductor device is from 5 degrees to 120 degrees.

In a second embodiments, a method of forming a semiconductor device is provided, the method including: creating a trench in a surface of the semiconductor device including a substrate; forming a retarding layer at the bottom of the trench; forming a source/drain region over the retarding layer in the trench; etching an opening through the substrate, the retarding layer, and a portion of the source/drain region where an etch rate through the substrate and the portion of the source/drain region is faster than an etch rate through the retarding layer when exposed to a same etch process for etching the substrate; and forming a through silicon via (TSV) in the opening.

In some embodiments, the method further includes: forming, before forming the source/drain region, a dielectric layer over the retarding layer; and forming a gap in the dielectric layer near the center of the dielectric layer, wherein a ratio between the distance the gap spans and the distance from an outside edge of the dielectric to a closest gap sidewall and is between 1 and 10.

In a third embodiment, a nano-FET (field effect transistor) is provided, including: a substrate, the substrate including a fin; isolation regions over the substrate and along opposing sides of the fin; a plurality of nanostructures over the fin; an source/drain region adjacent the plurality of nanostructures: a gate electrode over the plurality of nanostructures; a retarding layer between the substrate and the source/drain region that has a slower etching rate when exposed to an etch process than does the source/drain region and the substrate when exposed to the etch process; and a through silicon via (TSV) penetrating through the substrate, the retarding layer, and making electrical contact with the source/drain region.

In some embodiments, the nano-FET further includes a dielectric layer between the retarding layer and the source/drain region that has a gap near the center of the dielectric layer through which the TSV penetrates to make electrical contact with source/drain region. In some embodiments, the dielectric layer is between 1 nm and 10 nm thick, the gap has a horizontal span between 1 nm and 20 nm and is between 1 nm and 10 nm horizontally from an edge of the source/drain region, and an angle of the inside edge of the gap is from 10 degrees to 150 degrees measure from a line parallel to the major plane of a top surface of the substrate. In some embodiments, the retarding layer includes silicon and germanium described by the ratio Si₁₋ₓGeₓ, where 0.0≤X≤0.4, and a doped impurity in with a concentration between 1×10²⁰ and 5×10²⁰ atoms per centimeter cubed (atm/cm³). In some embodiments, the concentration of the impurity is a concentration gradient across a height of the retarding layer starting at a baseline concentration at a top of the retarding layer, rising to a peak concentration from 1 nm to 15 nm below the top of the retarding layer, and decreasing back toward the baseline concentrate at a bottom of the retarding layer. In some embodiments, the baseline concentration is between 1×10²⁰ atm/cm³ and 2×10²² atm/cm³, the peak concentration is between 1×10²⁰ atm/cm³ and 5×10²² atm/cm³, a ratio between the baseline concentration and the peak concentration 1.0 to 2.5, and baseline concentration is less than the peak concentration. In some embodiments, the retarding layer is between 1 nm and 30 nm thick, and a top of the retarding layer is located between 15 nm above and 15 nm below an interface between the substrate and a nanostructure of the plurality of nanostructures closest to the substrate. In some embodiments, the TSV extends between 5 nm and 15 nm above a top surface of the retarding layer towards the source/drain region. In some embodiments, the retarding layer is curved across a width of the source/drain region, and an angle between a tangent of a topmost surface of the retarding layer closest to the plurality of nanostructures and a line perpendicular to the major plane of the substrate is from 5 degrees to 120 degrees.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a source/drain region;
a retarding layer between the substrate and the source/drain region that has a slower etch rate when exposed to an etch than does the substrate and the source/drain region; and
a through silicon via (TSV) electrically connecting the source/drain region to a backside of the semiconductor device, wherein the TSV penetrates through the substrate, the retarding layer, and a portion of the source/drain region.

2. The semiconductor device of claim 1, further comprising a dielectric layer between the retarding layer and the source/drain region, wherein the TSV further penetrates through a gap in the dielectric layer.

3. The semiconductor device of claim 2, wherein a ratio of a thickness of the dielectric layer to the thickness of the retarding layer is between 1.0 and 20.0, the dielectric layer has a gap located towards the center of the dielectric layer, and wherein a ratio between the distance the gap spans and the distance from an outside edge of the dielectric to a closest gap sidewall is between 1 and 10.

4. The semiconductor device of claim 1, wherein the retarding layer is doped with an impurity have a concentration having a ratio between a peak concentration and a baseline concentration between 1.0 to 2.5.

5. The semiconductor device of claim 4, wherein the impurity concentration is a gradient starting at a baseline concentration at a top surface of the retarding layer, increasing to a peak concentration from 1 nm to 15 nm below the top surface of the retarding layer, and decreasing back towards the baseline concentration at a bottom surface of the retarding layer.

6. The semiconductor device of claim 4, wherein the semiconductor device is a n-type field effect transistor, the substrate comprises silicon, the retarding layer comprises Si₁₋ₓGeₓ where 0.0≤X≤0.4, the source/drain region is a p-type material, and the impurity is boron.

7. The semiconductor device of claim 4, wherein a top surface of the retarding layer is between 15 nm below a topmost surface of the substrate to 15 nm above the topmost surface of the substrate, and the retarding layer is between 1 nm and 30 nm thick.

8. The semiconductor device of claim 4, wherein the retarding layer is flat within process parameters across a width of the source/drain region.

9. The semiconductor device of claim 4, wherein the retarding layer is curved across a width of the source/drain region, and wherein an angle between a tangent of a topmost surface of the retarding layer at an interface of a trench enclosing the source/drain region and an imaginary line perpendicular to the major plane of the semiconductor device is from 5 degrees to 120 degrees.

10. A method of forming a semiconductor device, comprising:
creating a trench in a surface of the semiconductor device including a substrate;
forming a retarding layer at the bottom of the trench;
forming a source/drain region over the retarding layer in the trench;
etching an opening through the substrate, the retarding layer, and a portion of the source/drain region where an etch rate through the substrate and the portion of the source/drain region is faster than an etch rate through the retarding layer when exposed to a same etch process for etching the substrate; and
forming a through silicon via (TSV) in the opening.

11. The method forming the semiconductor device of claim 10, further comprising:
forming, before forming the source/drain region, a dielectric layer over the retarding layer; and
forming a gap in the dielectric layer near the center of the dielectric layer, wherein a ratio between the distance the gap spans and the distance from an outside edge of the dielectric to a closest gap sidewall and is between 1 and 10.

12. A nano-FET (field effect transistor), comprising:
a substrate, the substrate comprising a fin;
isolation regions over the substrate and along opposing sides of the fin;
a plurality of nanostructures over the fin;
an source/drain region adjacent the plurality of nanostructures:
a gate electrode over the plurality of nanostructures;
a retarding layer between the substrate and the source/drain region that has a slower etching rate when exposed to an etch process than does the source/drain region and the substrate when exposed to the etch process; and
a through silicon via (TSV) penetrating through the substrate, the retarding layer, and making electrical contact with the source/drain region.

13. The nano-FET of claim 12, further comprising:
a dielectric layer between the retarding layer and the source/drain region that has a gap near the center of the dielectric layer through which the TSV penetrates to make electrical contact with source/drain region.

14. The nano-FET of claim 13, wherein the dielectric layer is between 1 nm and 10 nm thick, the gap has a horizontal span between 1 nm and 20 nm and is between 1 nm and 10 nm horizontally from an edge of the source/drain region, and an angle of the inside edge of the gap is from 10 degrees to 150 degrees measure from a line parallel to the major plane of a top surface of the substrate.

15. The nano-FET of claim 12, wherein the retarding layer comprises silicon and germanium described by the ratio Si₁₋ₓGeₓ, where 0.0≤X≤0.4, and a doped impurity in with a concentration between 1×10²⁰ and 5×10²⁰ atoms per centimeter cubed (atm/cm³).

16. The nano-FET of claim 15, wherein the concentration of the impurity is a concentration gradient across a height of the retarding layer starting at a baseline concentration at a top of the retarding layer, rising to a peak concentration from 1 nm to 15 nm below the top of the retarding layer, and decreasing back toward the baseline concentrate at a bottom of the retarding layer.

17. The nano-FET of claim 16, wherein the baseline concentration is between 1×10²⁰ atm/cm³ and 2×10²² atm/cm³, the peak concentration is between 1×10²⁰ atm/cm³ and 5×10²² atm/cm³, a ratio between the baseline concentration and the peak concentration 1.0 to 2.5, and baseline concentration is less than the peak concentration.

18. The nano-FET of claim 12, wherein the retarding layer is between 1 nm and 30 nm thick, and a top of the retarding layer is located between 15 nm above and 15 nm below an interface between the substrate and a nanostructure of the plurality of nanostructures closest to the substrate.

19. The nano-FET of claim 12, wherein the TSV extends between 5 nm and 15 nm above a top surface of the retarding layer towards the source/drain region.

20. The nano-FET of claim 12, wherein the retarding layer is curved across a width of the source/drain region, and an angle between a tangent of a topmost surface of the retarding layer closest to the plurality of nanostructures and a line perpendicular to the major plane of the substrate is from 5 degrees to 120 degrees.
